(19) United States
(12) Patent Application Publication
(10) Pub. No.: US 2024/0355780 A1
(43) Pub. Date: Oct. 24, 2024

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Juhyeon KIM, Suwon-si (KR); Chajea JO, Suwon-si (KR)

(73) Assignee: SAMSUNG ELECTRONICS CO., LTD., Suwon-si (KR)

(21) Appl. No.: 18/387,707

(22) Filed: Nov. 7, 2023

(30) Foreign Application Priority Data
Apr. 19, 2023 (KR) 10-2023-0051465

(51) Int. Cl. H01L 25/065; H01L 23/00; H01L 23/31; H01L 23/498; H01L 23/522; H01L 23/528

(52) U.S. Cl. CPC H01L 25/0657; H01L 23/3128; H01L 23/49816; H01L 23/49822; H01L 23/5226; H01L 23/5283; H01L 24/08; H01L 2224/08146; H01L 2924/181

(57) ABSTRACT

Semiconductor packages and fabrication methods thereof are provided. A semiconductor package includes first and second structures. The first structure includes: a first semiconductor substrate that has an active surface on which a first semiconductor device is configured to be provided, and an inactive surface opposite to the active surface; a first through via that vertically penetrates the first semiconductor substrate and protrudes from the inactive surface of the first semiconductor substrate; a first protection layer that covers the inactive surface of the first semiconductor substrate and buries the first through via; and a first pad that penetrates at least a portion of the first protection layer and is coupled to the first through via. The second structure includes a second pad, the first structure and the second structure are bonded to each other, and the first pad and the second pad are in contact with each other.

### CROSS-REFERENCE TO RELATED APPLICATION

This U.S. nonprovisional application claims priority under 35 U.S.C. § 119 to Korean Patent Application No. 10-2023-0051465, filed on Apr. 19, 2023, in the Korean Intellectual Property Office, the disclosure of which is hereby incorporated by reference in its entirety.

### BACKGROUND

### 1. Field

Embodiments of the present disclosure relate to a directly bonded semiconductor package and a method of fabricating the same.

### 2. Description of Related Art

In the semiconductor industry, semiconductor devices that are higher capacity, thinner, and smaller, and electronic products using the same, have been demanded and thus various package techniques have been suggested. The various package techniques include a packaging technique in which a plurality of semiconductor chips are vertically stacked to achieve a high density chip stacking. This packaging technique enables semiconductor chips having various functions to be integrated in a smaller area than a conventional package consisting of one semiconductor chip.

A semiconductor package is provided to implement an integrated circuit chip for use in electronic products. A semiconductor package is typically configured such that a semiconductor chip is mounted on a printed circuit board and bonding wires or bumps are used to electrically connect the semiconductor chip to the printed circuit board. With the development of the electronic industry, research has been conducted to improve reliability and durability of semiconductor packages.

### SUMMARY

Some embodiments of the present disclosure provide a semiconductor package with increased structural stability and a method of fabricating the same.

Some embodiments of the present disclosure provide a method of fabricating a semiconductor package with less occurrence of failure and a semiconductor package fabricated by the same.

According to embodiments of the present disclosure, a semiconductor package is provided and includes a first structure and a second structure. The first structure includes: a first semiconductor substrate that has an active surface on which a first semiconductor device is configured to be provided, and an inactive surface opposite to the active surface; a first through via that vertically penetrates the first semiconductor substrate and protrudes from the inactive surface of the first semiconductor substrate; a first protection layer that covers the inactive surface of the first semiconductor substrate and buries the first through via; and a first pad that penetrates at least a portion of the first protection layer and is coupled to the first through via. The first protection layer includes: a first dielectric layer that is on the inactive surface of the first semiconductor substrate; a second dielectric layer on the first dielectric layer; and an etch stop layer between the first dielectric layer and the second dielectric layer and in contact with a lateral surface of the first pad. The second structure includes a second pad, the first structure and the second structure are bonded to each other, and the first pad and the second pad are in contact with each other.

According to embodiments of the present disclosure, a semiconductor package is provided and includes: a substrate; semiconductor chips on the substrate; and a molding layer on the substrate, the molding layer surrounding the semiconductor chips. Each of the semiconductor chips includes: a semiconductor substrate; first pads on an active surface of the semiconductor substrate; a dielectric pattern that surrounds the first pads and exposes one surface of the first pads; second pads on an inactive surface of the semiconductor substrate; a protection layer that surrounds the second pads and exposes one surface of the second pads; and through vias that vertically penetrate the semiconductor substrate and are connected to the second pads, wherein the protection layer includes a first dielectric layer, an etch stop layer, and a second dielectric layer that are sequentially stacked, the first dielectric layer and the second dielectric layer being spaced apart from each other across the etch stop layer, wherein a distance from the etch stop layer to the semiconductor substrate is greater than a distance from bottom surfaces of the second pads to the semiconductor substrate, and wherein one of the semiconductor chips is directly bonded to another one of the semiconductor chips, and the first pads of the one of the semiconductor chips are in contact with the second pads of the other one of the semiconductor chips.

According to embodiments of the present disclosure, a semiconductor package is provided and includes: a substrate; semiconductor chips stacked on the substrate; and a molding layer on the substrate, the molding layer surrounding the semiconductor chips. Each of the semiconductor chips includes: a semiconductor substrate; first pads on an active surface of the semiconductor substrate; a dielectric pattern that surrounds the first pads and exposes one surface of the first pads; a protection layer that is on an inactive surface of the semiconductor substrate and includes a first dielectric layer, an etch stop layer, a second dielectric layer, and a polish stop layer that are sequentially stacked; second pads that are in the protection layer and have one surface exposed by the protection layer; and through vias that vertically penetrate the semiconductor substrate and are connected to the second pads. wherein the etch stop layer is in contact with the second pads, and wherein one of the semiconductor chips is directly bonded to another one of the semiconductor chips, and the first pads of the one of the semiconductor chips are in contact with the second pads of the other one of the semiconductor chips.

According to embodiments of the present disclosure, a method of fabricating a semiconductor package is provided and includes: providing a semiconductor substrate; forming, in the semiconductor substrate, a through via that extends into the semiconductor substrate, from an active surface of the semiconductor substrate; performing a first thinning process on an inactive surface of the semiconductor substrate that causes the through via to protrude from the inactive surface of the semiconductor substrate; forming a first dielectric layer on the inactive surface of the semiconductor substrate, wherein the first dielectric layer buries the through via; performing a second thinning process on the first dielectric layer such that the through via becomes exposed from the first dielectric layer; sequentially forming an etch stop layer and a second dielectric layer on the first dielectric layer and the through via; forming a recess that exposes the through via by patterning the second dielectric layer and the etch stop layer, the etch stop layer defining an inner wall of the recess; and forming a pad connected to the through via by filling the recess with a conductive material.

### BRIEF DESCRIPTION OF DRAWINGS

FIG. 1 illustrates a cross-sectional view showing a semiconductor package according to some embodiments of the present disclosure.

FIGS. 2A to 2E illustrate enlarged views showing section A of FIG. 1.

FIG. 3 illustrates a cross-sectional view showing a semiconductor package according to some embodiments of the present disclosure.

FIG. 4 illustrates an enlarged view showing section B of FIG. 3.

FIG. 5 illustrates a cross-sectional view showing a semiconductor package according to some embodiments of the present disclosure.

FIG. 6 illustrates a cross-sectional view showing a semiconductor package according to some embodiments of the present disclosure.

FIG. 7 illustrates an enlarged view showing section C of FIG. 6.

FIG. 8 illustrates a cross-sectional view showing a semiconductor package according to some embodiments of the present disclosure.

FIG. 9A illustrates a cross-sectional view showing a part of a method of fabricating a semiconductor package according to some embodiments of the present disclosure.

FIG. 9B illustrates an enlarged view showing section D1 of FIG. 9A.

FIG. 10A illustrates a cross-sectional view showing a part of the method of fabricating the semiconductor package according to some embodiments of the present disclosure.

FIG. 10B illustrates an enlarged view showing section D2 of FIG. 10A.

FIG. 11A illustrates a cross-sectional view showing a part of the method of fabricating the semiconductor package according to some embodiments of the present disclosure.

FIG. 11B illustrates an enlarged view showing section D3 of FIG. 11A.

FIG. 12A illustrates a cross-sectional view showing a part of the method of fabricating the semiconductor package according to some embodiments of the present disclosure.

FIG. 12B illustrates an enlarged view showing section D4 of FIG. 12A.

FIG. 13A illustrates a cross-sectional view showing a part of the method of fabricating the semiconductor package according to some embodiments of the present disclosure.

FIG. 13B illustrates an enlarged view showing section D5 of FIG. 13A.

FIG. 14A illustrates a cross-sectional view showing a part of the method of fabricating the semiconductor package according to some embodiments of the present disclosure.

FIG. 14B illustrates an enlarged view showing section D6 of FIG. 14A.

FIG. 15A illustrates a cross-sectional view showing a part of the method of fabricating the semiconductor package according to some embodiments of the present disclosure.

FIG. 15B illustrates an enlarged view showing section D7 of FIG. 15A.

FIG. 16A illustrates a cross-sectional view showing a step of a method of fabricating a semiconductor package according to some embodiments of the present disclosure.

FIG. 16B illustrates an enlarged view showing section E1 of FIG. 16A.

FIG. 17A illustrates a cross-sectional view showing a step of the method of fabricating the semiconductor package according to some embodiments of the present disclosure.

FIG. 17B illustrates an enlarged view showing section E2 of FIG. 17A.

FIG. 18A illustrates a cross-sectional view showing a step of the method of fabricating the semiconductor package according to some embodiments of the present disclosure.

FIG. 18B illustrates an enlarged view showing section E3 of FIG. 18A.

FIG. 19A illustrates a cross-sectional view showing a step of the method of fabricating the semiconductor package according to some embodiments of the present disclosure.

FIG. 19B illustrates an enlarged view showing section E4 of FIG. 19A.

FIG. 20A illustrates a cross-sectional view showing a step of the method of fabricating the semiconductor package according to some embodiments of the present disclosure.

FIG. 20B illustrates an enlarged view showing section E5 of FIG. 20A.

FIG. 21A illustrates a cross-sectional view showing a step of the method of fabricating the semiconductor package according to some embodiments of the present disclosure.

FIG. 21B illustrates an enlarged view showing section E6 of FIG. 21A.

FIG. 22A illustrates a cross-sectional view showing a step of the method of fabricating the semiconductor package according to some embodiments of the present disclosure.

FIG. 22B illustrates an enlarged view showing section E7 of FIG. 22A.

FIG. 23A illustrates a cross-sectional view showing a step of the method of fabricating the semiconductor package according to some embodiments of the present disclosure.

FIG. 23B illustrates an enlarged view showing section E8 of FIG. 23A.

FIGS. 24 to 29 illustrate cross-sectional views showing a method of fabricating a semiconductor package according to some embodiments of the present disclosure.

### DETAILED DESCRIPTION

The following will now describe semiconductor packages according to non-limiting example embodiments of the present disclosure with reference to the accompanying drawings.

It will be understood that when an element or layer is referred to as being “on.” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

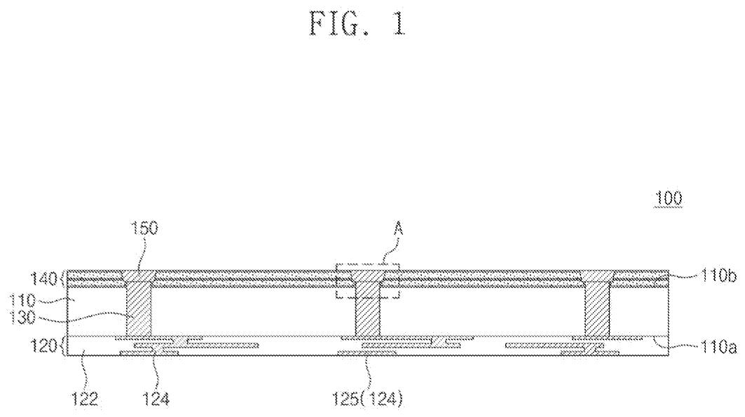

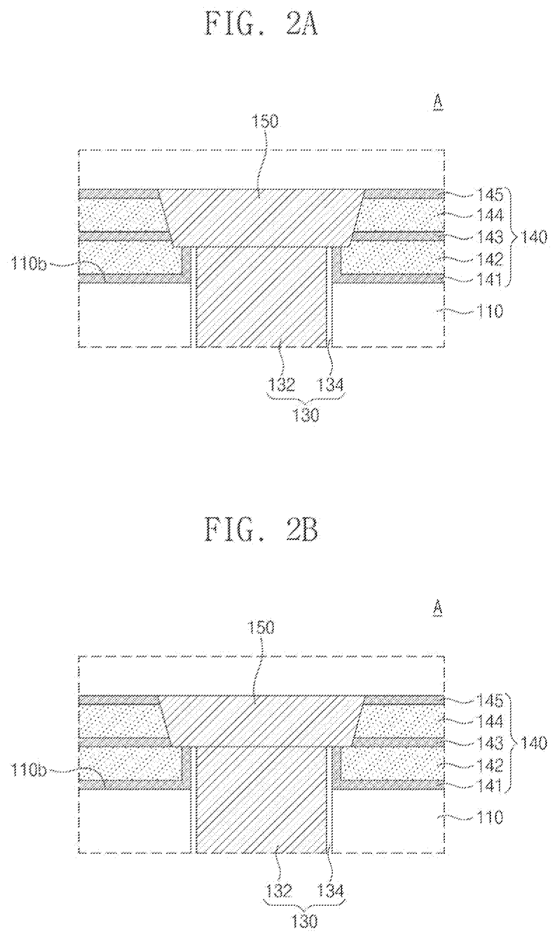

FIG. 1 illustrates a cross-sectional view showing a semiconductor package according to some embodiments of the present disclosure. FIGS. 2A and 2B illustrate enlarged views showing section A of FIG. 1.

Referring to FIGS. 1 and 2A, a semiconductor package may include at least one semiconductor chip 100.

The semiconductor chip 100 may be a logic chip. Alternatively, the semiconductor chip 100 may be a memory chip, such as dynamic random access memory (DRAM), static random access memory (SRAM), magnetic random access memory (MRAM), or Flash memory. The semiconductor chip 100 may have a front surface and a rear surface. In this description, the language “front surface” may be defined as an active surface of an integrated element in a semiconductor chip or a surface on which are formed a plurality of pads of a semiconductor chip, and the language “rear surface” may be defined as an opposite surface that faces in a direction opposite of a facing direction of the front surface. The semiconductor chip 100 may include a base layer 110, a circuit layer 120 provided on a bottom surface 110a of the base layer 110, a protection layer 140 provided on a top surface 110b of the base layer 110, and at least one through via 130 that penetrates the base layer 110.

The base layer 110 may include a semiconductor material. For example, the base layer 110 may be a monocrystalline silicon (Si) substrate. Semiconductor devices may be provided on the base layer 110. In detail, an integrated element or integrated circuits may be formed on a lower portion of the base layer 110. For example, the bottom surface 110a of the base layer 110 may have thereon a wiring pattern, an integrated element such as a transistor, or a passive element such as a resistor, a capacitor, or an inductor. The bottom surface 110a may be a front surface of the base layer 110, and the top surface 110b may be a rear surface of the base layer 110.

The circuit layer 120 may be provided on the bottom surface 110a of the base layer 110. The circuit layer 120 may be electrically connected to the integrated element or the integrated circuits formed in the base layer 110. For example, the circuit layer 120 may have a dielectric pattern 122 and a wiring pattern 124 provided in the dielectric pattern 122, and the wiring pattern 124 may be coupled to the integrated element or the integrated circuits formed in the base layer 110. A portion of the wiring pattern 124 may be exposed at a bottom of the circuit layer 120, and the exposed portion of the wiring pattern 124 may be a first chip pad 125 of the semiconductor chip 100. The first chip pad 125 may be provided in plural. The semiconductor chip 100 may have a bottom surface, or an active surface, on which the circuit layer 120 is provided.

The through via 130 may vertically penetrate the base layer 110. One end of the through via 130 may be exposed at the top surface 110b of the base layer 110. The through via 130 may protrude from the top surface 110b of the base layer 110, or the rear surface of the semiconductor chip 100. For example, the one end of the through via 130 may be located at a higher level than a level of the top surface 110b of the base layer 110. Another end of the through via 130 may extend toward the front surface of the semiconductor chip 100 to come into connection with the circuit layer 120. The through via 130 may be coupled to the wiring pattern 124 of the circuit layer 120.

The through via 130 may include a conductive layer 132 and a via barrier layer 134. The conductive layer 132 may have a pillar shape that vertically penetrates the base layer 110. The conductive layer 132 may include a metallic material, such as copper (Cu) or tungsten (W). The via barrier layer 134 may surround a circumferential surface of the conductive layer 132. The via barrier layer 134 may not cover a top surface of the conductive layer 132. For example, the top surface of the conductive layer 132 may be exposed without being covered with the via barrier layer 134. The via barrier layer 134 may be provided to insulate the conductive layer 132 and the base layer 110 from each other or to prevent a material of the conductive layer 132 from diffusing into the base layer 110. The via barrier layer 134 may include conductive metal nitride, such as titanium nitride (TiN) or tantalum nitride (TaN). Alternatively, the via barrier layer 134 may include a dielectric layer.

A second chip pad 150 may be provided on the top surface 110b of the base layer 110. The second chip pad 150 may be positioned on the through via 130. For example, the second chip pad 150 may be in contact with a top surface of the through via 130. A bottom surface of the second chip pad 150 may be in contact with the top surface of the conductive layer 132 and a top surface of the via barrier layer 134. The second chip pad 150 may not contact the circumferential surface of the through via 130 that protrudes from the top surface 110b of the base layer 110. Alternatively, the second chip pad 150 may contact at least a portion of the circumferential surface of the through via 130 that protrudes from the top surface 110b of the base layer 110. The following will now discuss an embodiment of FIG. 2A in which the circumferential surface of the through via 130 is not in contact with the second chip pad 150. Since the through via 130 protrudes from the top surface 110b of the base layer 110, the second chip pad 150 may be spaced apart from the top surface 110b of the base layer 110. A width of the bottom surface of the second chip pad 150 may be greater than a width of the top surface of the through via 130. For example, the through via 130 may cover a center of the top surface of the second chip pad 150, and an edge of the bottom surface of the second chip pad 150 may be exposed without being covered by the through via 130. The second chip pad 150 may have a width that increases with increasing distance from the base layer 110. The second chip pad 150 may be provided in plural. In this case, each of the second chip pads 150 may be connected to one of a plurality of the through vias 130. The second chip pad 150 may include a metallic material, such as copper (Cu).

According to embodiments, the second chip pad 150 may further include a seed layer that covers the bottom and lateral surfaces of the second chip pad 150. The seed layer may include metal, such as gold (Au).

The protection layer 140 may be provided on the top surface 110b of the base layer 110. The protection layer 140 may cover the top surface 110b of the base layer 110, and may bury the through via 130 that protrudes from the top surface 110b of the base layer 110. For example, the through via 130 may penetrate a portion of the protection layer 140. The protection layer 140 may surround the second chip pad 150 on the top surface 110b of the base layer 110. The top surfaces of the protection layer 140 and the second chip pad 150 may be substantially flat and coplanar with each other. For example, the second chip pad 150 may be positioned in an upper portion of the protection layer 140, and the through via 130 may penetrate a lower portion of the protection layer 140 to be coupled to the bottom surface of the second chip pad 150. The protection layer 140 may be in contact with the bottom and outer lateral surfaces of the second chip pad 150 and with the circumferential surface of the through via 130. The protection layer 140 may include a liner layer 141, a first dielectric layer 142, an etch stop layer 143, a second dielectric layer 144, and a polish stop layer 145 that are sequentially disposed on the top surface 110b of the base layer 110.

The liner layer 141 may be provided on the top surface 110b of the base layer 110. The liner layer 141 may conformally cover the top surface 110b of the base layer 110 and the circumferential surface of the through via 130. The liner layer 141 may extend from the top surface 110b of the base layer 110 along the circumferential surface of the through via 130, and one end of the liner layer 141 may be in contact with the bottom surface of the second chip pad 150. The liner layer 141 may have a thickness smaller than a distance that the through via 130 protrudes from the top surface 110b of the base layer 110. The liner layer 141 may include a dielectric material. For example, the liner layer 141 may include silicon nitride (SiN).

The first dielectric layer 142 may be disposed on the liner layer 141. The first dielectric layer 142 may cover the top surface 110b of the base layer 110 and may surround the through via 130. For example, the liner layer 141 may be interposed between the first dielectric layer 142 and the base layer 110, and may extend between the first dielectric layer 142 and the circumferential surface of the through via 130. A top surface of the first dielectric layer 142 may be located at a higher level than a level of the top surface of the through via 130. A distance between a contact interface, between the through via 130 and the second chip pad 150, and the base layer 110 may be smaller than a distance between the top surface of the first dielectric layer 142 and the base layer 110, and/or the contact interface between the through via 130 and the second chip pad 150 may be lower than a level of the top surface of the first dielectric layer 142. Therefore, the first dielectric layer 142 may be in contact with the bottom surface of the second chip pad 150 and a lower portion of the lateral surface of the second chip pad 150. The top surface of the first dielectric layer 142 may be substantially flat. The first dielectric layer 142 may include a dielectric material. The first dielectric layer 142 may include a different material from a material of the liner layer 141. For example, the first dielectric layer 142 may include silicon oxide (SiO).

The etch stop layer 143 may be disposed on the first dielectric layer 142. The etch stop layer 143 may entirely cover the top surface of the first dielectric layer 142. The etch stop layer 143 may extend along the top surface of the first dielectric layer 142 to contact the lateral surface of the second chip pad 150. A bottom surface of the etch stop layer 143 may be located at a higher level than a level of the bottom surface of the second chip pad 150. Alternatively, as shown in FIG. 2B, the top surface of the first dielectric layer 142 and the bottom surface of the etch stop layer 143 may be located at the same level as a level of the bottom surface of the second chip pad 150 or a level of the contact point between the through via 130 and the second chip pad 150. For example, the bottom surface of the second chip pad 150 may be coplanar with the bottom surface of the etch stop layer 143. The following description will now focus on the embodiment of FIG. 2A. The etch stop layer 143 may be shaped as a substantially flat planarized layer. For example, a top surface of the etch stop layer 143 may be substantially flat. The etch stop layer 143 may include a dielectric material. The etch stop layer 143 may include a material having an etch selectivity with respect to the first dielectric layer 142 and the second dielectric layer 144 which will be discussed below. For example, the etch stop layer 143 may include silicon nitride (SiN).

The second dielectric layer 144 may be disposed on the etch stop layer 143. The second dielectric layer 144 may cover the top surface of the etch stop layer 143. The second dielectric layer 144 may extend along the top surface of the etch stop layer 143 to contact the lateral surface of the second chip pad 150. The etch stop layer 143 may separate the second dielectric layer 144 and the first dielectric layer 142 from each other. For example, the etch stop layer 143 may run between the first dielectric layer 142 and the second dielectric layer 144 to contact the second chip pad 150, and may separate the first dielectric layer 142 and the second dielectric layer 144 from each other. The second dielectric layer 144 may have a uniform thickness. As the etch stop layer 143 entirely covers the top surface of the first dielectric layer 142, and as the etch stop layer 143 is shaped as a flat planarized layer, the second dielectric layer 144 may have a plate shape, and a top surface of the second dielectric layer 144 may be substantially flat. This will be further discussed below in detail in describing a method of fabricating a semiconductor package. The top surface of the second dielectric layer 144 may be located at a lower level than a level of the top surface of the second chip pad 150. The second dielectric layer 144 may include a dielectric material. For example, the second dielectric layer 144 may include silicon oxide (SiO).

The polish stop layer 145 may be disposed on the second dielectric layer 144. The polish stop layer 145 may cover the top surface of the second dielectric layer 144. The polish stop layer 145 may extend along the top surface of the second dielectric layer 144 to contact the lateral surface of the second chip pad 150. The polish stop layer 145 may be shaped as a substantially flat planarized layer. The polish stop layer 145 may have a substantially flat top surface. The top surface of the polish stop layer 145 may be coplanar with a top surface of the second chip pad 150. The polish stop layer 145 may include a dielectric material. For example, the polish stop layer 145 may include silicon nitride (SiN).

According to some embodiments of the present disclosure, the etch stop layer 143 interposed between the first dielectric layer 142 and the second dielectric layer 144 may completely cover the top surface of the first dielectric layer 142 and the bottom surface of the second dielectric layer 144, and may be shaped as a planarized layer. The second dielectric layer 144 and the polish stop layer 145 formed on the etch stop layer 143 may also be shaped as a planarized layer or a plate, and the protection layer 140 and the second chip pad 150 may have their top surfaces substantially flat and coplanar with each other. Therefore, in a direct bonding process where semiconductor chips are in direct contact with each other, another semiconductor chip may be easily bonded onto a top surface of the semiconductor chip 100.

In the embodiments that follow, components the same as those discussed with reference to FIGS. 1, 2A, and 2B are allocated the same reference numerals thereto, and a repetitive explanation thereof may be omitted or abridged for convenience of description. The following mainly describes differences between the embodiment of FIGS. 1, 2A, and 2B and other embodiments described below.

FIGS. 2C to 2E illustrate enlarged views showing section A of FIG. 1.

Referring to FIGS. 1 and 2C, the protection layer 140 of the semiconductor chip 100 may not include the polish stop layer 145. In this case, a top surface of the second dielectric layer 144 may be located at the same level as a level of a top surface of the second chip pad 150. The second dielectric layer 144 and the second chip pad 150 may have their top surfaces substantially flat and coplanar with each other.

Alternatively, referring to FIGS. 1 and 2D, the protection layer 140 of the semiconductor chip 100 may not include the liner layer 141. In this case, the first dielectric layer 142 may be in contact with the top surface 110b of the base layer 110, and may extend along the top surface 110b of the base layer 110 to contact a circumferential surface of the through via 130 and a bottom surface of the second chip pad 150.

Alternatively, referring to FIGS. 1 and 2E, the semiconductor chip 100 may include neither the liner layer 141 nor the polish stop layer 145. In this case, the first dielectric layer 142 may be in contact with the top surface 110b of the base layer 110, and may extend along the top surface 110b of the base layer 110 to contact a circumferential surface of the through via 130 and a bottom surface of the second chip pad 150. The second dielectric layer 144 and the second chip pad 150 may have their top surfaces located at the same level. The top surfaces of the second dielectric layer 144 and the second chip pad 150 may be substantially flat and coplanar with each other

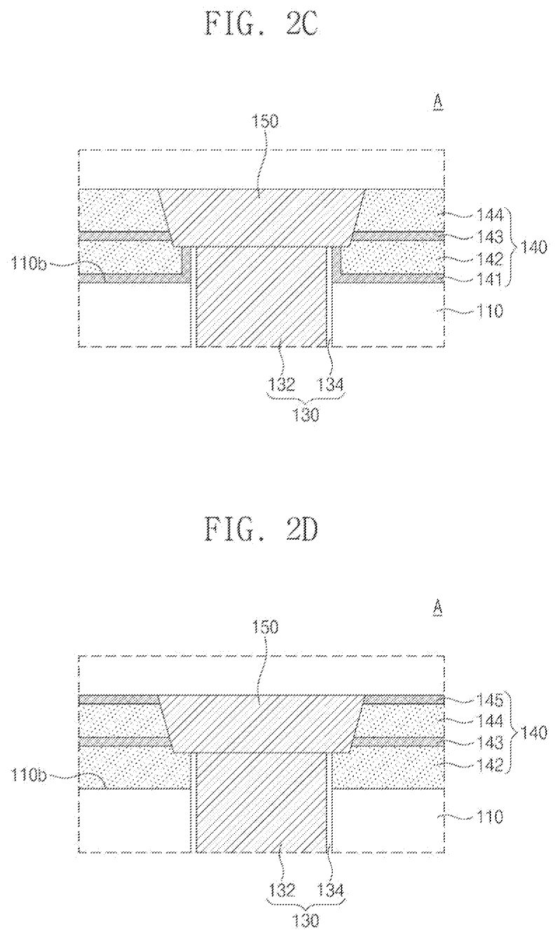

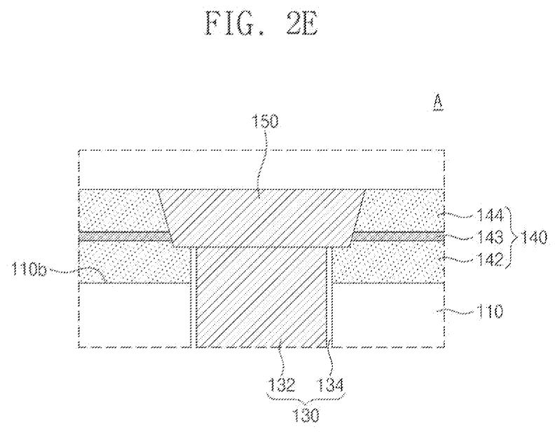

FIG. 3 illustrates a cross-sectional view showing a semiconductor package according to some embodiments of the present disclosure. FIG. 4 illustrates an enlarged view showing section B of FIG. 3.

Referring to FIGS. 3 and 4, a semiconductor package may include a lower structure and an upper structure that are stacked on each other. In the embodiment of FIGS. 3 and 4, the lower structure may include a first semiconductor chip 101, and the upper structure may include a second semiconductor chip 102. For example, the semiconductor package may include the first semiconductor chip 101 and the second semiconductor chip 102 that are bonded to each other. Each of the first semiconductor chip 101 and the second semiconductor chip 102 may each be the semiconductor chip 100 discussed with reference to FIGS. 1 and 2A to 2E.

The second semiconductor chip 102 may be mounted on the first semiconductor chip 101. For example, the second semiconductor chip 102 may be disposed on the first semiconductor chip 101. A front surface of the second semiconductor chip 102 may face a rear surface of the first semiconductor chip 101. The first semiconductor chip 101 and the second semiconductor chip 102 may be vertically aligned with each other. For example, the second chip pad 150 of the first semiconductor chip 101 may be vertically aligned with the first chip pad 125 of the second semiconductor chip 102. The front surface of the second semiconductor chip 102 may be in contact with the rear surface of the first semiconductor chip 101.

On an interface between the first semiconductor chip 101 and the second semiconductor chip 102, the protection layer 140 of the first semiconductor chip 101 may be in contact with the dielectric pattern 122 of the circuit layer 120 of the second semiconductor chip 102. In this case, the dielectric pattern 122 and the protection layer 140 may constitute a hybrid bonding between metals (e.g., copper (Cu)). In this description, the term “hybrid bonding” may denote a bonding in which two components of the same kind are merged at an interface therebetween. The dielectric pattern 122 and the protection layer 140 bonded to each other may have a continuous configuration, and an invisible interface may be present between the dielectric pattern 122 and the protection layer 140. For example, the dielectric pattern 122 and the protection layer 140 may be formed of the same material, and thus no interface may be present between the dielectric pattern 122 and the protection layer 140. The dielectric pattern 122 and the protection layer 140 may be provided as one component. For example, the dielectric pattern 122 and the protection layer 140 may be combined to form a single unitary body. Embodiments of the present disclosure, however, are not limited thereto. The dielectric pattern 122 and the protection layer 140 may be formed of different materials from each other. The dielectric pattern 122 and the protection layer 140 may have no continuous configuration, and a visible interface may be present between the dielectric pattern 122 and the protection layer 140.

According to some embodiments of the present disclosure, the protection layers 140 of the first semiconductor chip 101 and the second semiconductor chip 102 may have flat shapes. For example, the protection layer 140 of the first semiconductor chip 101 may contact the second semiconductor chip 102 and may have a flat shape. A flat bonding interface may be present between the protection layer 140 of the first semiconductor chip 101 and the dielectric pattern 122 of the second semiconductor chip 102, and a gap may be absent between the dielectric pattern 122 and the protection layer 140. Therefore, it may be possible to provide a semiconductor package of which structural stability is increased and in which good bonding is provided between the dielectric pattern 122 and the protection layer 140 or between the first semiconductor chip 101 and the second semiconductor chip 102.

The first semiconductor chip 101 may be connected to the second semiconductor chip 102. For example, the first semiconductor chip 101 and the second semiconductor chip 102 may be in contact with each other. On an interface between the first semiconductor chip 101 and the second semiconductor chip 102, the second chip pads 150 of the first semiconductor chip 101 may be bonded to the first chip pads 125 of the second semiconductor chip 102. In this case, the second chip pads 150 and the first chip pads 125 may constitute an intermetallic hybrid bonding. For example, the second chip pad 150 and the first chip pad 125 bonded to each other may have a continuous configuration, and an invisible interface may be present between the second chip pad 150 and the first chip pad 125. The second chip pad 150 and the first chip pad 125 may be formed of the same material, and thus no interface may be provided between the second chip pad 150 and the first chip pad 125. The second chip pad 150 and the first chip pad 125 may be provided as one component. For example, the second chip pad 150 and the first chip pad 125 may be bonded to constitute a single unitary body.

According to some embodiments of the present disclosure, a flat bonding interface may be present between the second chip pad 150 of the first semiconductor chip 101 and the first chip pad 125 of the second semiconductor chip 102, and a gap may be absent between the second chip pad 150 and the first chip pad 125. Therefore, it may be possible to provide a semiconductor package which has good bonding between the second chip pad 150 and the first chip pad 125 and a good electrical connection between the first semiconductor chip 101 and the second semiconductor chip 102.

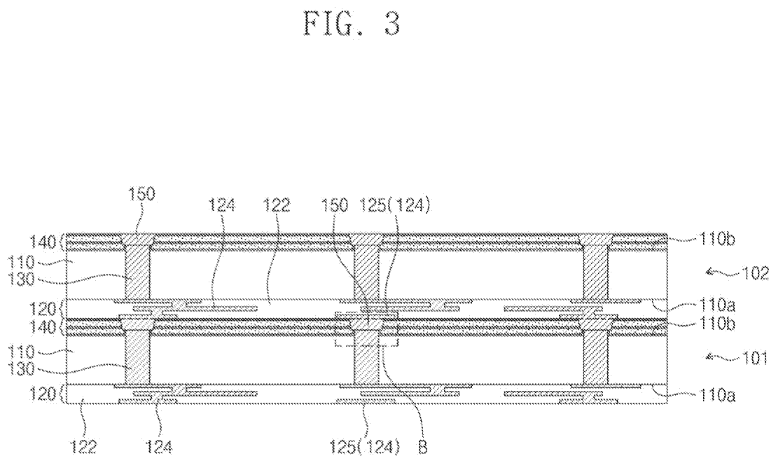

FIG. 5 illustrates a cross-sectional view showing a semiconductor package according to some embodiments of the present disclosure.

Referring to FIG. 5, a base substrate 200 may be provided. The base substrate 200 may include an integrated circuit therein. For example, the base substrate 200 may be a semiconductor chip including an electronic element such as a transistor. For example, the base substrate 200 may be a wafer-level die formed of a semiconductor such as silicon (Si). FIG. 5 depicts that the base substrate 200 is a semiconductor chip, but embodiments of the present disclosure are not limited thereto. According to some embodiments of the present disclosure, the base substrate 200 may be a substrate, such as a printed circuit board (PCB), which does not include an electronic element such as a transistor. A silicon wafer may have a thickness smaller than a thickness of a printed circuit board (PCB). The following will describe an example in which the base substrate 200 is a base semiconductor chip.

The base substrate 200 (e.g., the base semiconductor chip) may include a base semiconductor substrate 210, a base circuit layer 220, and base vias 230.

The base semiconductor substrate 210 may include a semiconductor material. For example, the base semiconductor substrate 210 may be a monocrystalline silicon (Si) substrate. An integrated element or integrated circuits may be formed on a lower portion of the base semiconductor substrate 210. For example, the bottom surface of the base semiconductor substrate 210 may be provided with a wiring pattern, an integrated element such as a transistor, or a passive element such as a resistor, a capacitor, or an inductor. The bottom surface of the base semiconductor substrate 210 may be a front surface of the base semiconductor substrate 210, and a top surface of the base semiconductor substrate 210 may be a rear surface of the base semiconductor substrate 210. For example, the base substrate 200 may be a logic chip.

The base circuit layer 220 may be provided on the bottom surface of the base semiconductor substrate 210. The base circuit layer 220 may be electrically connected to the integrated element or the integrated circuits formed in the base semiconductor substrate 210. For example, the base circuit layer 220 may include a dielectric pattern 222 and a wiring pattern 224 provided in the dielectric pattern 222, and the wiring pattern 224 may be coupled to the integrated element or the integrated circuits formed in the base semiconductor substrate 210. A portion of the wiring pattern 224 may be exposed at a bottom surface of the base circuit layer 220, and the exposed portion of the wiring pattern 224 may be an external pad 225 of the base substrate 200. The external pad 225 may be provided in plural. According to some embodiments, the base circuit layer 220 may not be provided.

The base vias 230 may vertically penetrate the base semiconductor substrate 210. For example, the base vias 230 may be exposed at the top surface of the base semiconductor substrate 210. A dielectric layer may be provided to surround the base vias 230. For example, the dielectric layer may include at least one selected from among silicon oxide (SiO), silicon nitride (SiN), silicon oxynitride (SiON), and low-k dielectrics.

The base substrate 200 may be provided with external terminals 260 on a bottom surface thereof. The external terminals 260 may be disposed on the external pads 225. The external terminals 260 may be electrically connected to the base circuit layer 220 and the base vias 230. The external terminal 260 may be an alloy that includes at least one selected from among tin (Sn), silver (Ag), copper (Cu), nickel (Ni), bismuth (Bi), indium (In), antimony (Sb), and cerium (Ce).

The base substrate 200 may further include mount pads 250 and a base protection layer 240.

The mount pads 250 may be disposed on the top surface of the base semiconductor substrate 210. The mount pads 250 may be provided on and coupled to the base vias 230. The mount pads 250 may be coupled through the base vias 230 to the base circuit layer 220.

The top surface of the base semiconductor substrate 210 may be provided thereon with the base protection layer 240 that surrounds the mount pads 250 and portions of the base vias 230 that protrude from the top surface of the base semiconductor substrate 210. The base protection layer 240 may expose the mount pads 250. A top surface of the base protection layer 240 may be coplanar with top surfaces of the mount pads 250. The base protection layer 240 may be substantially the same as or similar to the protection layer 140 discussed with reference to FIGS. 1 and 2A to 2E. For example, the base protection layer 240 may include a liner layer, a first dielectric layer, an etch stop layer, a second dielectric layer, and a polish stop layer on the base semiconductor substrate 210. Embodiments of the present disclosure, however, are not limited thereto.

A chip stack may be disposed on the base substrate 200. The chip stack may include a plurality of semiconductor chips 100 and 103. The semiconductor chips 100 and 103 may be of the same kind. For example, each of the semiconductor chips 100 and 103 may be the same as the semiconductor chip 100 discussed with reference to FIGS. 1 and 2A to 2E. Among the semiconductor chips 100 and 103, an uppermost semiconductor chip 103 may have a similar structure as the structures of the other semiconductor chips 100, but may include none of the through vias 130, the protection layer 140, and the second chip pads 150. The uppermost semiconductor chip 103 may have a thickness greater than thicknesses of the other semiconductor chips 100. The semiconductor chips 100 and 103 may be memory chips. The semiconductor chips 100 and 103 may be sequentially stacked on the base substrate 200. In the present embodiment, it is disclosed that four semiconductor chips (e.g., three semiconductor chips 100 and one semiconductor chip 103) are stacked on the base substrate 200, but two or four or more semiconductor chips may be provided. The semiconductor chips 100 and 103 may each have a width greater than a width of the base substrate 200. The semiconductor chips 100 and 103 may be vertically aligned with each other. A mounting or bonding between neighboring semiconductor chips 100 and 103 may be the same as or similar to that discussed with reference to FIGS. 3 and 4.

The chip stack may be mounted on the base substrate 200. The first chip pads 125 of s lowermost one among the semiconductor chips 100 may be vertically aligned with the mount pads 250 of the base substrate 200. The base substrate 200 and the lowermost one of the semiconductor chips 100 may be in contact with each other. On an interface between the base substrate 200 and the lowermost one of the semiconductor chips 100, the mount pads 250 of the base substrate 200 may be bonded to the first chip pads 125 of the lowermost one of the semiconductor chips 100. In this case, the mount pads 250 and the first chip pads 125 may constitute an intermetallic hybrid bonding. Alternatively, differently from that shown, the chip stack may be flip-chip mounted on the base substrate 200. For example, connection terminals, such as solder balls, may be provided between the mount pads 250 of the base substrate 200 and the first chip pads 125 of the lowermost one of the semiconductor chips 100.

FIG. 5 depicts that an active surface of the lowermost one of the semiconductor chips 100 is bonded onto an inactive surface of the base substrate 200, but embodiments of the present disclosure are not limited thereto. According to some embodiments, an active surface of the base substrate 200 may face the active surface of the lowermost one of the semiconductor chips 100. In this case, base circuit layer 220 of the base substrate 200 may be in contact with the circuit layer 120 of the lowermost one of the semiconductor chisp 100, and the external pad 225 of the base circuit layer 220 may be bonded to the first chip pad 125 of the circuit layer 120. The external terminals 260 may be provided on the mount pads 250 of the base substrate 200, wherein the mount pads 250 are directed downwards. The following description will focus on the embodiment of FIG. 5.

A molding layer 300 may be provided on the base substrate 200. The molding layer 300 may cover a top surface of the base substrate 200. The molding layer 300 may surround the chip stack. For example, the molding layer 300 may cover lateral surfaces of the semiconductor chips 100 and 103. A top surface of the molding layer 300 may be coplanar with a top surface of the uppermost semiconductor chip 103. The molding layer 300 may protect the chip stack. The molding layer 300 may include a dielectric material. For example. the molding layer 300 may include an epoxy molding compound (EMC). Differently from that shown, the molding layer 300 may be formed to cover the chip stack. For example, the molding layer 300 may cover a rear surface of the uppermost semiconductor chip 103.

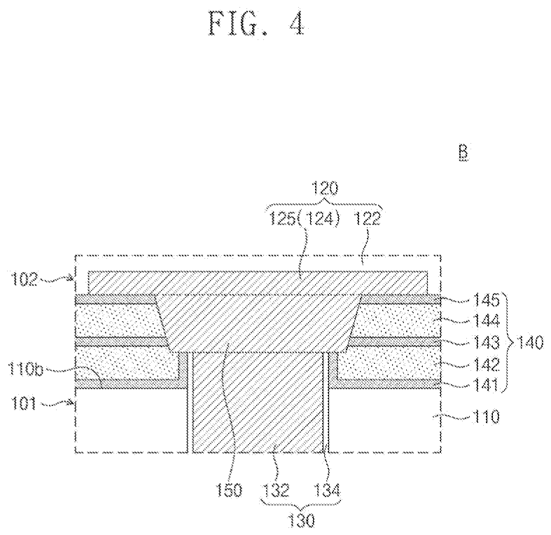

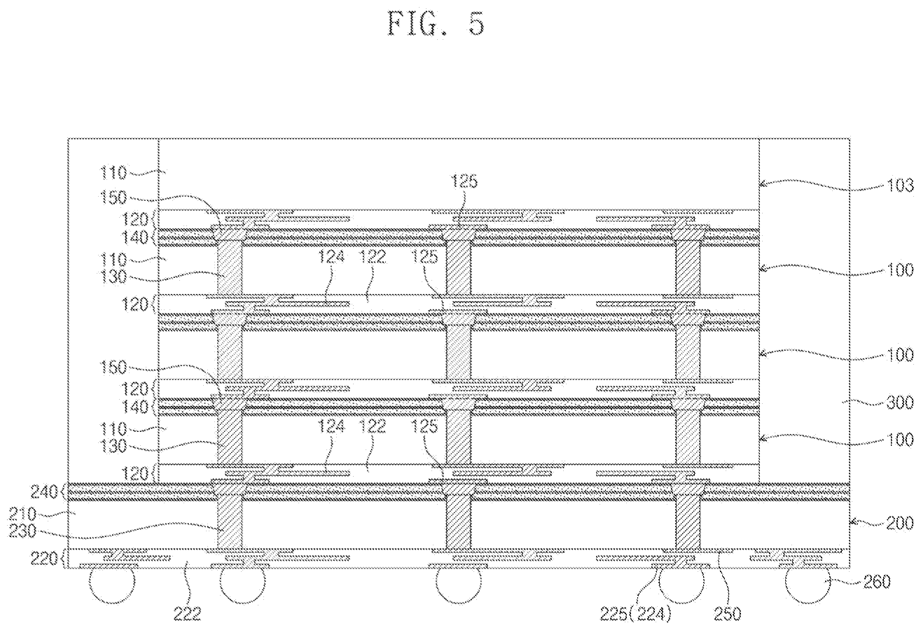

FIG. 6 illustrates a cross-sectional view showing a semiconductor package according to some embodiments of the present disclosure. FIG. 7 illustrates an enlarged view showing section C of FIG. 6.

Referring to FIGS. 6 and 7, a semiconductor package may include at least one semiconductor chip 104. The semiconductor chip 104 may include a base layer 110, a circuit layer 120 provided on a bottom surface) 110a (e.g., front surface) of the base layer 110, a protection layer 140 provided on a top surface 110b (e.g., rear surface) of the base layer 110, and a through via 130 that penetrates the base layer 110.

Differently from the embodiments of FIGS. 1 and 2A to 2E, the protection layer 140 of the semiconductor chip 104 may extend onto one side of the base layer 110. The following description will focus on the protection layer 140 of the semiconductor chip 104.

A first dielectric layer 142 may be provided on the top surface 110b of the base layer 110. The first dielectric layer 142 may cover the top surface 110b of the base layer 110, and may extend onto one side of the base layer 110 to cover a lateral surface of the base layer 110 and a lateral surface of the circuit layer 120. The first dielectric layer 142 may surround the through via 130 on the top surface 110b of the base layer 110. A top surface of the first dielectric layer 142 may be located at a higher level than a level of a top surface of the through via 130. A contact interface between the through via 130 and a second chip pad 150 may be closer to the base layer 110 than the top surface of the first dielectric layer 142.

A liner layer 141 may be interposed between the first dielectric layer 142 and the base layer 110. For example, the liner layer 141 may be interposed between the first dielectric layer 142 and the top surface 110b of the base layer 110, between the first dielectric layer 142 and the lateral surface of the base layer 110, and between the first dielectric layer 142 and the lateral surface of the circuit layer 120. The liner layer 141 may extend from the top surface 110b of the base layer 110 toward a space between the first dielectric layer 142 and a circumferential surface of the through via 130, and thus one end of the liner layer 141 may be in contact with a bottom surface of the second chip pad 150. In addition, the liner layer 141 may extend onto a bottom surface of the first dielectric layer 142. Embodiments of the present disclosure, however, are not limited thereto, and the liner layer 141 may not cover the bottom surface of the first dielectric layer 142.

An etch stop layer 143 may be disposed on the first dielectric layer 142. The etch stop layer 143 may entirely cover the top surface of the first dielectric layer 142. The etch stop layer 143 may extend along the top surface of the first dielectric layer 142 to contact a lateral surface of the second chip pad 150. A bottom surface of the etch stop layer 143 may be located at a higher level than a level of the bottom surface of the second chip pad 150. Alternatively, the top surface of the first dielectric layer 142 and the bottom surface of the etch stop layer 143 may be located at the same level as the level of the bottom surface of the second chip pad 150 and the level of the contact interface between the through via 130 and the second chip pad 150. The etch stop layer 143 may be shaped as a substantially flat planarized layer.

A second dielectric layer 144 may be disposed on the etch stop layer 143. The second dielectric layer 144 may cover a top surface of the etch stop layer 143. The second dielectric layer 144 may extend along the top surface of the etch stop layer 143 to contact the lateral surface of the second chip pad 150. The etch stop layer 143 may separate the second dielectric layer 144 and the first dielectric layer 142 from each other. The second dielectric layer 144 may have a uniform thickness. The second dielectric layer 144 may have a plate shape, and a top surface of the second dielectric layer 144 may be substantially flat. The top surface of the second dielectric layer 144 may be located at a lower level than a level of a top surface of the second chip pad 150.

A polish stop layer 145 may be disposed on the second dielectric layer 144. The polish stop layer 145 may cover the top surface of the second dielectric layer 144. The polish stop layer 145 may extend along the top surface of the second dielectric layer 144 to contact the lateral surface of the second chip pad 150. The polish stop layer 145 may be shaped as a substantially flat planarized layer. The polish stop layer 145 may have a substantially flat top surface. The top surface of the polish stop layer 145 may be coplanar with the top surface of the second chip pad 150.

According to some embodiments of the present disclosure, the protection layer 140 that extends onto the lateral surface of the base layer 110 may be used to adjust a width of the semiconductor chip 104. Thus, the semiconductor chip 104 may be easily bonded to another semiconductor chip or an electronic element each having a size different from a size of the semiconductor chip 104.

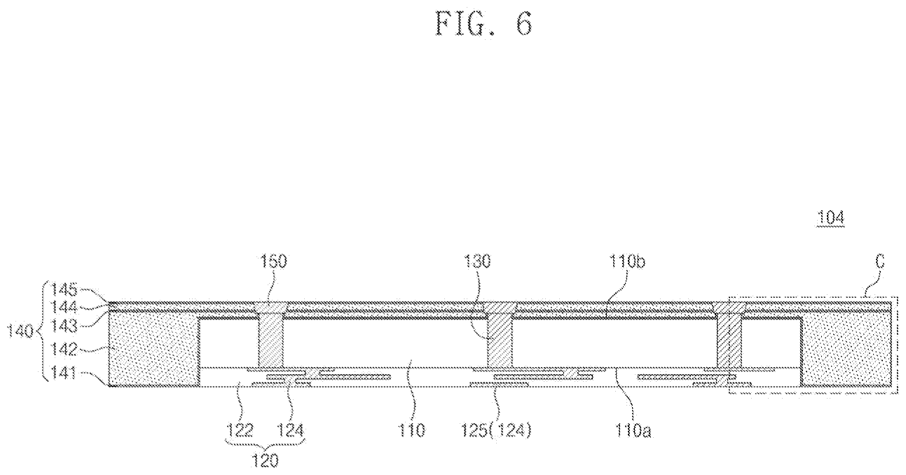

FIG. 8 illustrates a cross-sectional view showing a semiconductor package according to some embodiments of the present disclosure.

Referring to FIG. 8, a third semiconductor chip 104 may be provided. The third semiconductor chip 104 may be substantially the same as or similar to the semiconductor chip 104 discussed with respect to FIGS. 6 and 7. In addition, the third semiconductor chip 104 may further include a conductive post 147. On one side of the base layer 110, the conductive post 147 may vertically penetrate the protection layer 140. For example, one end of the conductive post 147 may penetrate the liner layer 141 to be exposed at one surface of the liner layer 141. Another end of the conductive post 147 may vertically penetrate the first dielectric layer 142. The conductive post 147 may be provided in plural. The conductive post 147 may include metal, such as copper (Cu) or tungsten (W). According to embodiments, the conductive post 147 may further include a seed layer or a barrier layer each of which surrounds a circumferential surface of the conductive post 147. One of a plurality of second chip pads 150 in the third semiconductor chip 104 may be coupled to the conductive post 147. For example, the one of the second chip pads 150 may vertically penetrate the polish stop layer 145, the second dielectric layer 144, and the etch stop layer 143, thereby being coupled to the conductive post 147.

A fourth semiconductor chip 400 may be disposed on the third semiconductor chip 104. The fourth semiconductor chip 400 may be positioned on an active surface of the third semiconductor chip 104. For example, the fourth semiconductor chip 400 may be positioned on the circuit layer 120 of the third semiconductor chip 104 and on the protection layer 140 on one side of the circuit layer 120. The fourth semiconductor chip 400 may include a semiconductor substrate 410 and a circuit layer 420.

The semiconductor substrate 410 may include a semiconductor material. For example, the semiconductor substrate 410 may be a monocrystalline silicon (Si) substrate. An integrated element or integrated circuits may be formed on a lower portion of the semiconductor substrate 410. For example, the bottom surface of the semiconductor substrate 410 may be provided thereon with a wiring pattern, an integrated element such as a transistor, or a passive element such as a resistor, a capacitor, or an inductor. The bottom surface of the semiconductor substrate 410 may be a front surface of the semiconductor substrate 410, and a top surface of the semiconductor substrate 410 may be a rear surface of the semiconductor substrate 410.

The circuit layer 420 may be provided on the bottom surface of the semiconductor substrate 410. The circuit layer 420 may be electrically connected to the integrated element or the integrated circuits formed in the semiconductor substrate 410. For example, the circuit layer 420 may have a dielectric pattern 422 and a wiring pattern 424 provided in the dielectric pattern 422, and the wiring pattern 424 may be coupled to the integrated element or the integrated circuits formed in the semiconductor substrate 410. A portion of the wiring pattern 424 may be exposed on a bottom surface of the circuit layer 420, and the exposed portion of the wiring pattern 424 may a third chip pad 425 of the fourth semiconductor chip 400. The third chip pad 425 may be provided in plural. The fourth semiconductor chip 400 may be provided with the circuit layer 420 on a bottom surface thereof, and the bottom surface of the fourth semiconductor chip 400 may be an active surface of the fourth semiconductor chip

The fourth semiconductor chip 400 may be mounted on the third semiconductor chip 104. For example, the fourth semiconductor chip 400 may be disposed on the third semiconductor chip 104. A front surface of the fourth semiconductor chip 400 may face a front surface of the third semiconductor chip 104. The third semiconductor chip 104 and the fourth semiconductor chip 400 may be vertically aligned with each other. For example, the conductive post 147 and the first chip pad 125 of the third semiconductor chip 104 may be vertically aligned with third chip pads 425 of the fourth semiconductor chip 400. The front surface of the third semiconductor chip 104 may be in contact with the front surface of the fourth semiconductor chip 400.

The third semiconductor chip 104 may be connected to the fourth semiconductor chip 400. For example, the third semiconductor chip 104 and the fourth semiconductor chip 400 may be in contact with each other. On an interface between the third semiconductor chip 104 and the fourth semiconductor chip 400, the conductive post 147 and the first chip pad 125 of the third semiconductor chip 104 may be bonded to the third chip pads 425 of the fourth semiconductor chip 400. In this case, an intermetallic hybrid bonding may be achieved between the first chip pad 125 and the third chip pad 425 and between the conductive post 147 and the third chip pad 425. For example, the first chip pad 125 and the third chip pad 425 bonded to each other may have a continuous configuration, and the conductive post 147 and the third chip pad 425 bonded to each other may have a continuous configuration. An invisible interface may be present between the first chip pad 125 and the third chip pad 425 and between the conductive post 147 and the third chip pad 425.

A redistribution substrate 500 may be provided below the third semiconductor chip 104. The redistribution substrate 500 may be in direct contact with a bottom surface of the third semiconductor chip 104, or a bottom surface of the protection layer 140 of the third semiconductor chip 104 and a bottom surface of the second chip pad 150.

The redistribution substrate 500 may include one or more substrate wiring layers that are stacked on each other. Each of the substrate wiring layers may include a substrate dielectric pattern 510 and a substrate wiring pattern 520 in the substrate dielectric pattern 510. When the substrate wiring layer is provided in plural, the substrate wiring pattern 520 of one of the substrate wiring layers may be electrically connected to the substrate wiring pattern 520 of adjacent another substrate wiring layer.

The substrate dielectric pattern 510 may include a dielectric polymer or a photo-imageable dielectric (PID). For example, the photo-imageable dielectric may include at least one selected from among a photosensitive polyimide (PI), polybenzoxazole (PBO), phenolic polymers, and benzocyclobutene polymers. Alternatively, the substrate dielectric pattern 510 may include a dielectric material. For example, the substrate dielectric pattern 510 may include silicon oxide (SiO), silicon nitride (SiN), silicon oxynitride (SiON), or dielectric polymers.

The substrate wiring pattern 520 may be provided in the substrate dielectric pattern 510. The substrate wiring pattern 520 may be provided on a bottom surface of the substrate dielectric pattern 510. The substrate wiring pattern 520 may horizontally extend on the bottom surface of the substrate dielectric pattern 510. The substrate wiring pattern 520 may protrude from the bottom surface of the substrate dielectric pattern 510. On the bottom surface of the substrate dielectric pattern 510, the substrate wiring pattern 520 may be covered with another substrate dielectric pattern 510 disposed thereunder. The substrate wiring pattern 520 provided in a lowermost substrate wiring layer may be redistribution pads for mounting a semiconductor package on an external substrate, a motherboard, external device, or so forth. As discussed above, the substrate wiring pattern 520 may be a line or pad portion of the substrate wiring layer. In such a configuration, the substrate wiring pattern 520 may be a component for horizontal redistribution in the substrate wiring layer. For example, as shown in FIG. 8, the substrate wiring pattern 520 may connect the redistribution pads to the second chip pads 150 of the third semiconductor chip 104. For example, the conductive post 147 may correspond to a vertical connector that electrically connects the redistribution substrate 500 to the fourth semiconductor chip 400. FIG. 8 depicts example electrical connection of the substrate wiring pattern 520, and a shape and arrangement of the substrate wiring pattern 520 is not limited to the shape and arrangement shown in FIG. 8. The substrate wiring pattern 520 may include a conductive material. For example, the substrate wiring pattern 520 may include copper (Cu).

The substrate wiring pattern 520 may have a damascene structure. For example, the substrate wiring pattern 520 may have a head portion and a tail portion that are integrally connected to each other. The head and tail portions of the substrate wiring pattern 520 may have an inverse T-shape cross-section.

External terminals 530 may be provided on the redistribution pads of the redistribution substrate 500. The external terminals 530 may include solder balls or solder bumps, and based on type and arrangement of the external terminals 530, a semiconductor package may be provided in the form of one of a ball grid array (BGA) type, a fine ball-grid array (FBGA) type, and a land grid array (LGA) type.

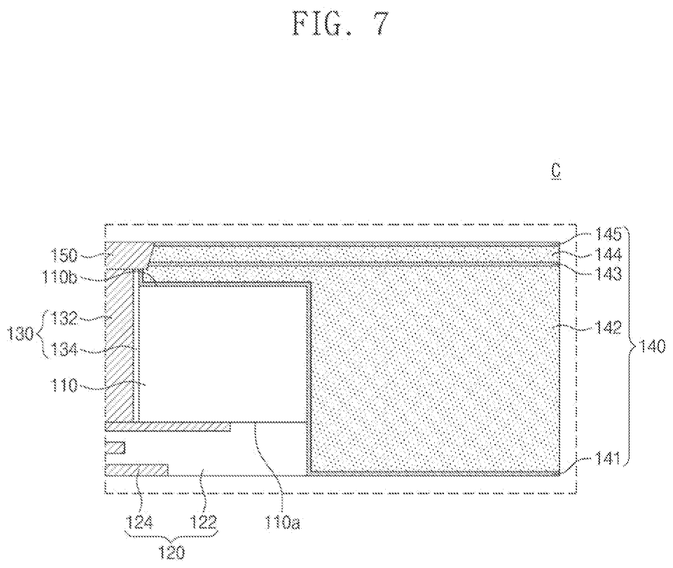

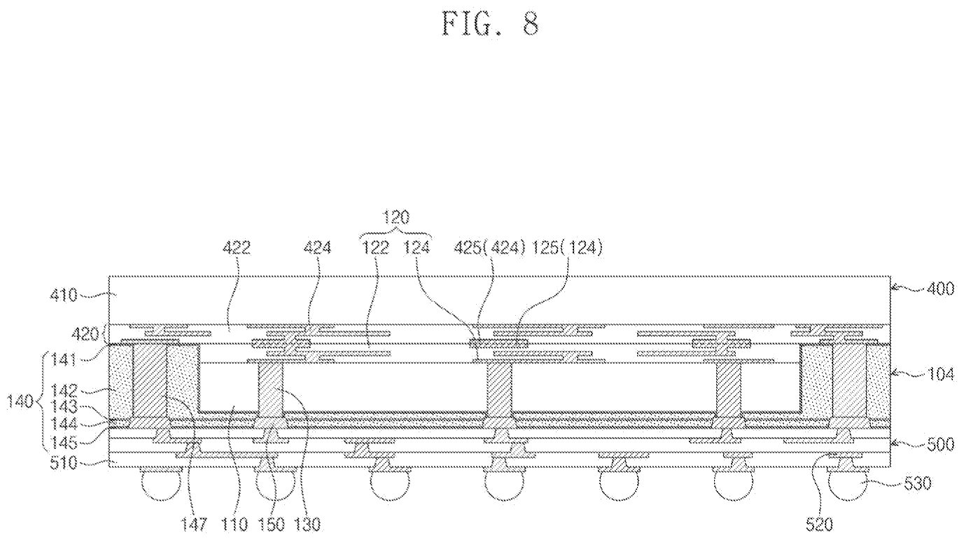

FIGS. 9A, 10A, 11A, 11A, 12A, 13A, 14A, and 15A illustrate cross-sectional views showing a method of fabricating a semiconductor package according to some embodiments of the present disclosure. FIGS. 9B, 10B, 11B, 12B, 13B, 14B, and 15B illustrate enlarged views showing sections D1, D2, D3, D4, D5, D6, and D7 of FIGS. 9A, 10A, 11A, 11A, 12A, 13A, 14A, and 15A, respectively.

Referring to FIGS. 9A and 9B, a typical procedure may be employed to form a semiconductor chip on a semiconductor substrate. For example, integrated circuits such as transistors may be formed on an active surface of the semiconductor substrate. The semiconductor substrate may correspond to a base layer 110 of the semiconductor chip. A through hole may be formed to extend into the base layer 110 from an active surface of the base layer 110 (e.g., the active surface of the semiconductor substrate), and then the through hole may be filled with a conductive layer 132 of a conductive material to form a through via 130. The through via 130 may not completely penetrate the base layer 110. For example, the through via 130 may extend from the active surface of the base layer 110, but may not reach an inactive surface of the base layer 110. Before the through hole is filled with the conductive layer 132, a via barrier layer 134 may be formed. The via barrier layer 134 may be formed to cover an inner lateral surface and a bottom surface of the through hole, and also to cover a circumferential surface and a top surface of the through via 130. A dielectric pattern 122 and a wiring pattern 124 may be formed on the active surface of the base layer 110, and thus a circuit layer 120 may be formed.

A carrier substrate 900 may be provided. The carrier substrate 900 may be a dielectric substrate including glass or polymer, or may be a conductive substrate including metal. According to embodiments, an adhesive member may be provided on a top surface of the carrier substrate 900. For example, the adhesive member may include a glue tape. According to some embodiments, a base chip may be provided to replace the carrier substrate 900. In this case, the circuit layer 120 of the semiconductor chip may be coupled to chip pads of the base chip.

The base layer 110 may be provided on the carrier substrate 900. For example, the base layer 110 may be attached to the carrier substrate 900 to allow the circuit layer 120 to contact the carrier substrate 900. Therefore, the inactive surface of the base layer 110 may be directed in an upward direction from the carrier substrate 900.

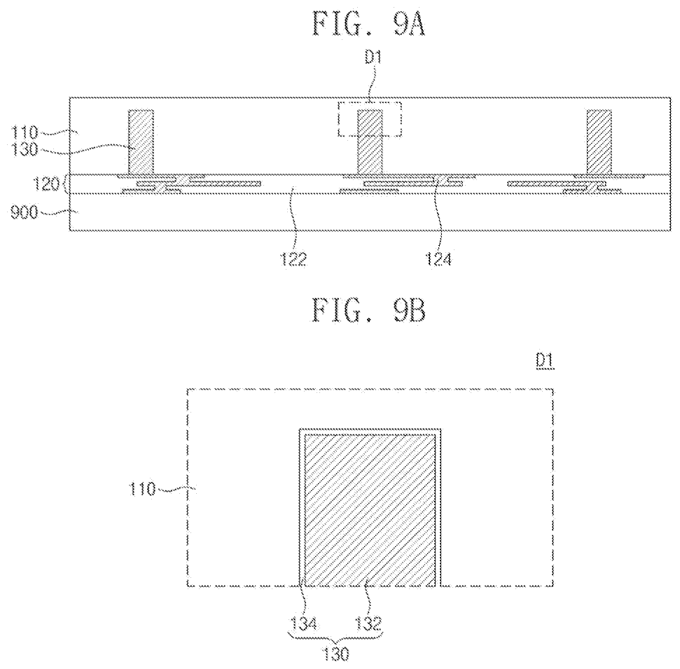

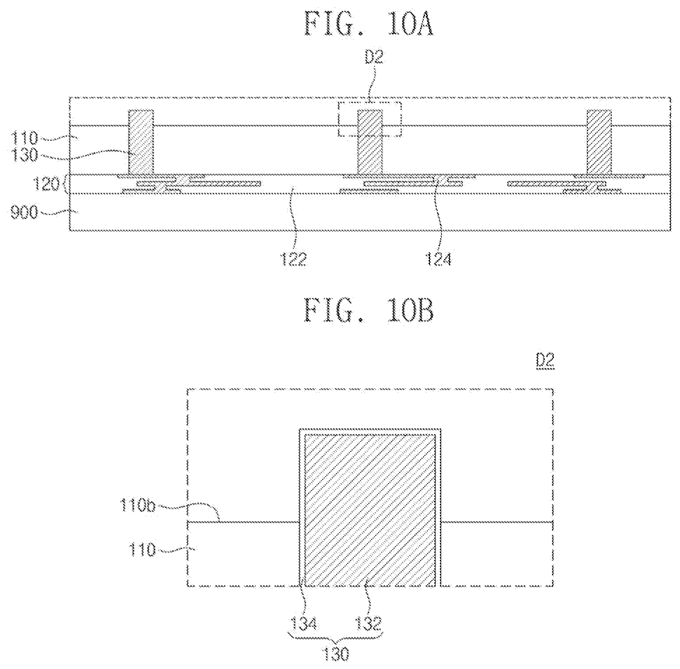

Referring to FIGS. 10A and 10B, a portion of the base layer 110 may be removed. For example, an upper portion of the base layer 110 may be etched. The removal of the upper portion of the base layer 110 may be performed until the top surfaces of the through vias 130 are exposed. A top surface 110b of the base layer 110 may be located at a different level from a level of the top surfaces of the through vias 130. For example, in the process that removes the upper portion of the base layer 110, the base layer 110 formed of silicon may be etched or polished, and the through vias 130 formed of metal may not be etched or polished. Therefore, after the removal of the upper portion of the base layer 110, the through vias 130 may protrude from the top surface 110b of the base layer 110.

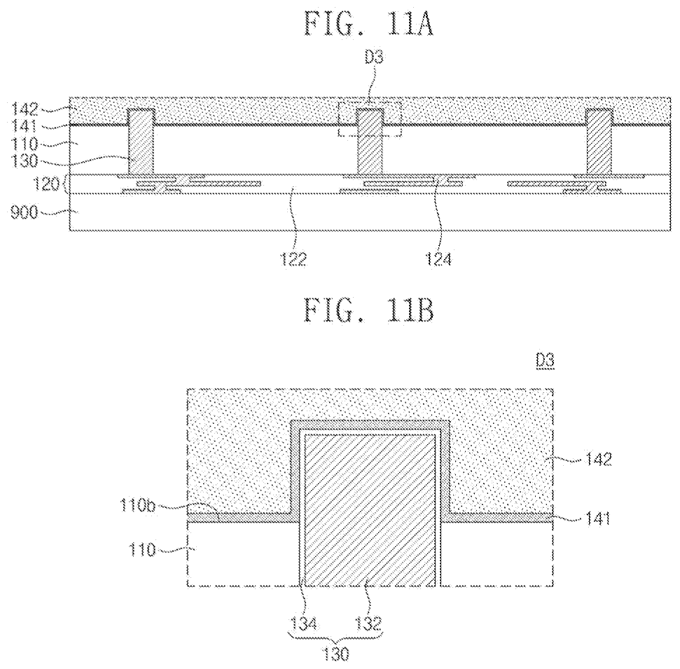

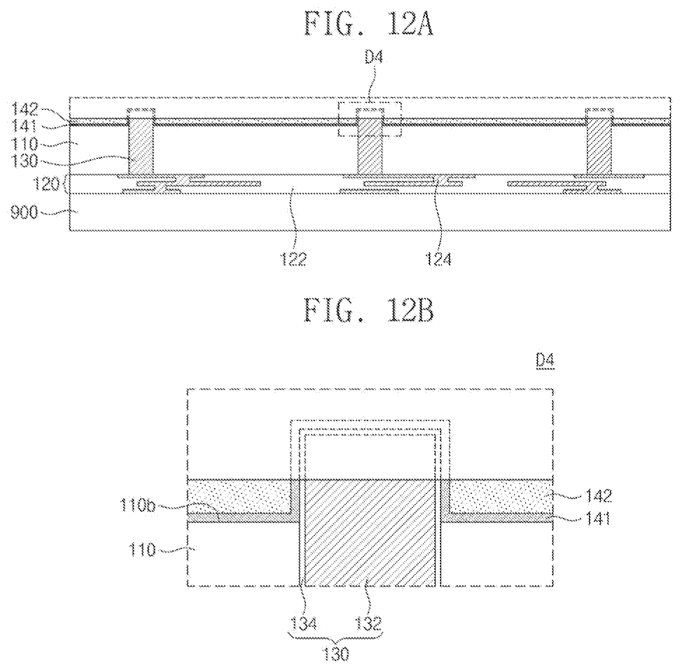

Referring to FIGS. 11A and 11B, a liner layer 141 may be formed on the base layer 110. The liner layer 141 may be formed to conformally cover the base layer 110 and the through vias 130 that protrude from the top surface 110b of the base layer 110. For example, the liner layer 141 may conformally cover the top surface 110b of the base layer 110, and may also conformally cover the circumferential surfaces and the top surfaces of the through vias 130.

A first dielectric layer 142 may be formed on the liner layer 141. For example, a chemical vapor deposition (CVD) process may be used to form the first dielectric layer 142. The first dielectric layer 142 may completely bury the through vias 130 while covering the top surface 110b of the base layer 110. Thus, the first dielectric layer 142 may completely cover the liner layer 141.

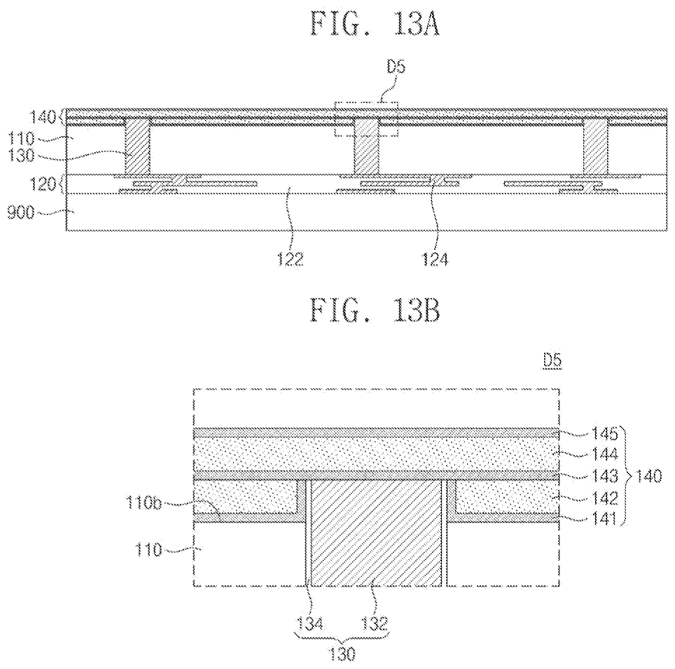

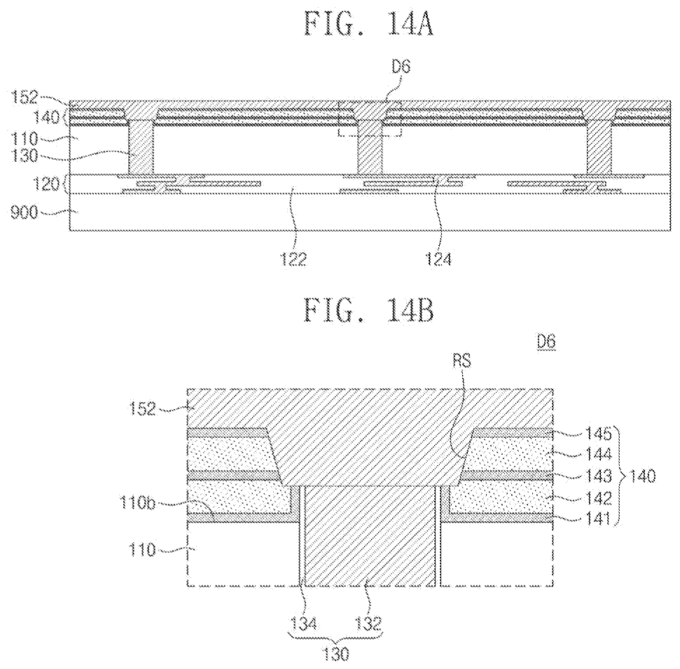

Referring to FIGS. 12A and 12B, a thinning process may be performed on the first dielectric layer 142. For example, a grinding process or a chemical mechanical polishing (CMP) process may be performed on a top surface of the first dielectric layer 142. The thinning process may be executed until the top surfaces of the through vias 130 are exposed. For example, the thinning process may remove portions of the first dielectric layer 142, the liner layer 141, and the via barrier layer 134 positioned on a top surface of the conductive layer 132 of the through via 130. Therefore, the conductive layers 132 of the through vias 130 may be exposed at the top surfaces thereof. After the thinning process, the top surface of the conductive layer 132, a top end of the via barrier layer 134, a top end of the liner layer 141, and the top surface of the first dielectric layer 142 may be substantially flat and coplanar with each other.

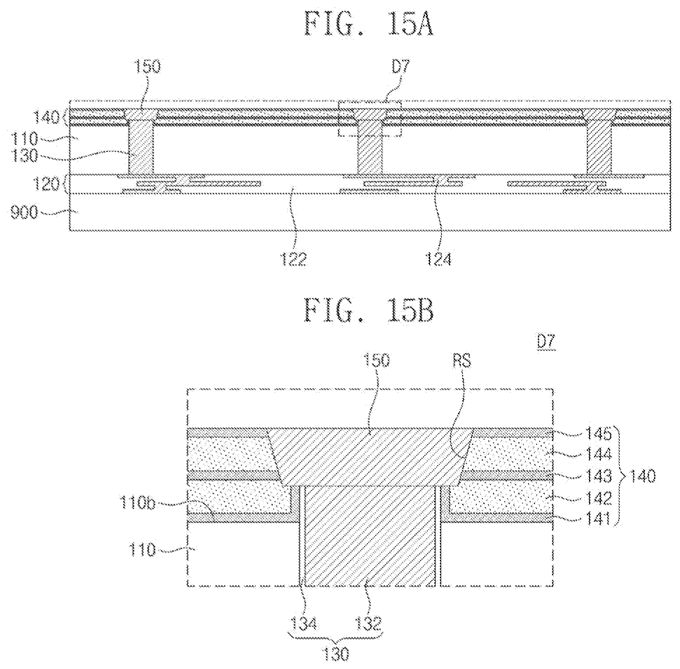

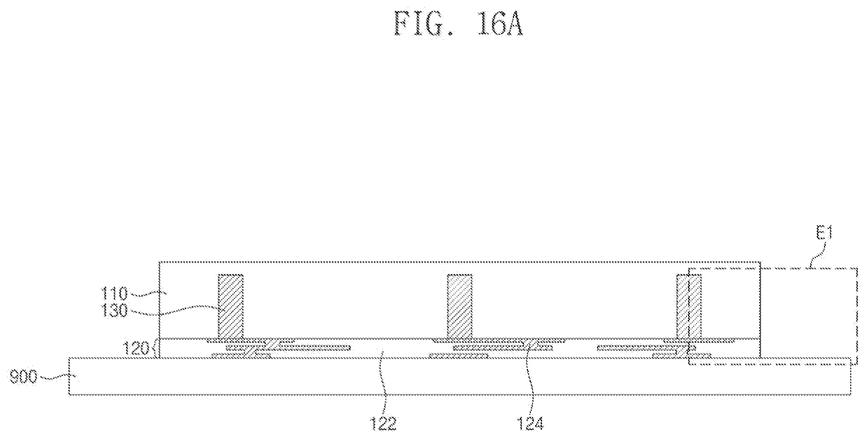

Referring to FIGS. 13A and 13B, an etch stop layer 143 may be formed on the base layer 110. The etch stop layer 143 may be formed to cover the first dielectric layer 142. For example, the etch stop layer 143 may conformally cover the top surface of the conductive layer 132, the top end of the via barrier layer 134, the top end of the liner layer 141, and the top surface of the first dielectric layer 142. In accordance with shapes of the top surface of the conductive layer 132, the top end of the via barrier layer 134, the top end of the liner layer 141, and the top surface of the first dielectric layer 142, the etch stop layer 143 may be shaped as a substantially flat planarized layer.

According to some embodiments of the present disclosure, the etch stop layer 143 may cover an entirety of top surfaces of the through vias 130, the liner layer 141, and the first dielectric layer 142 that are formed on the base layer 110, and a top surface of the etch stop layer 143 may be flat. Thus, other material layers (e.g., a second dielectric layer 144 and a polish stop layer 145) deposited on the etch stop layer 143 may each have a flat shape, and as a result, a flat top surface may be given to the second dielectric layer 144 or the polish stop layer 145 each of which corresponds to an inactive surface of a semiconductor chip. When another semiconductor chip (or a wiring substrate) is directly bonded onto the inactive surface of the semiconductor chip, no gap or pore may be present between the semiconductor chips, and an easy bonding may be achieved between the semiconductor chips. In conclusion, it may be possible to provide a semiconductor chip with increased structural stability and improved electrical connection properties and also to provide a semiconductor package including the semiconductor chip.

Alternatively, in a comparative embodiment, when the etch stop layer 143 exposes a portion of the first dielectric layer 142, there may be a step difference between the top surface of the etch stop layer 143 and the top surface of the first dielectric layer 142, and no flat shape may be given to other material layers (e.g., a second dielectric layer 144 and a polish stop layer 145) formed on the etch stop layer 143 and the first dielectric layer 142. In this case, when another semiconductor chip is directly bonded onto an inactive surface of a semiconductor chip, a gap or pore may be present between the semiconductor chips, and the semiconductor chips may experience lamination issues or electrical shorts.

A second dielectric layer 144 may be formed on the etch stop layer 143. For example, a chemical vapor deposition (CVD) process may be used to form the second dielectric layer 144. As the etch stop layer 143 covers an entirety of top surfaces of the through vias 130, the liner layer 141, and the first dielectric layer 142, the etch stop layer 143 may separate the second dielectric layer 144 from the first dielectric layer 142. In accordance with a shape of the top surface of the etch stop layer 143, the second dielectric layer 144 may be shaped as a substantially flat planarized layer.

A polish stop layer 145 may be formed on the second dielectric layer 144. The polish stop layer 145 may be formed to cover the second dielectric layer 144. In accordance with a shape of the top surface of the second dielectric layer 144, the polish stop layer 145 may be shaped as a substantially flat planarized layer.

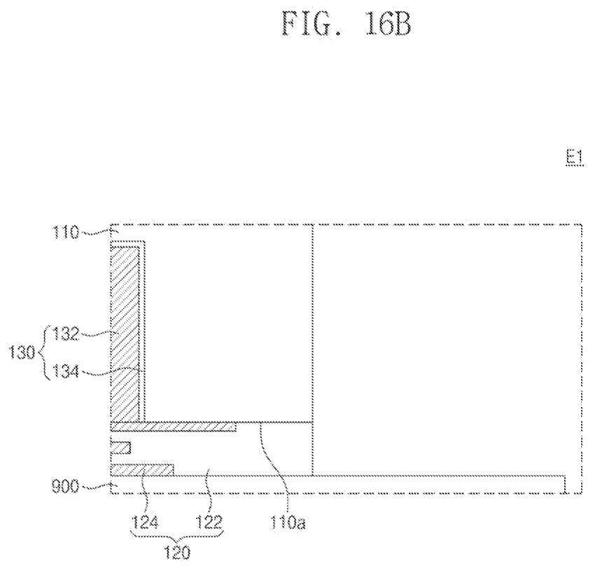

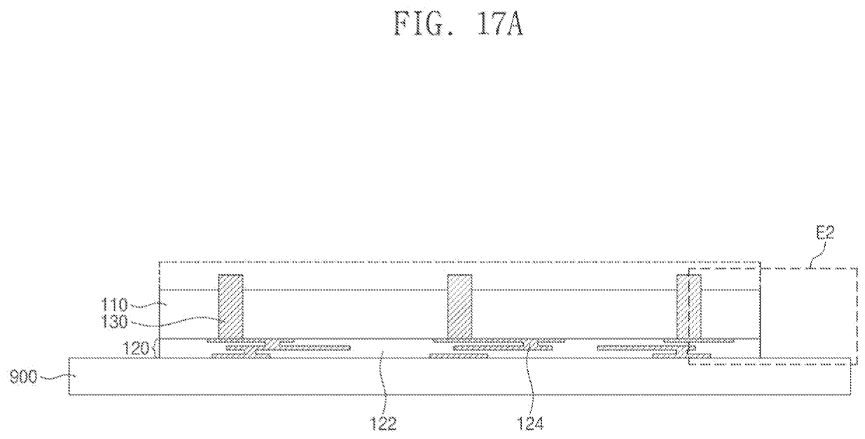

Referring to FIGS. 14A and 14B, a patterning process may be performed on the protection layer 140. In the patterning process, recesses RS may be formed on the protection layer 140 to expose the through vias 130. The patterning process may be performed until bottom surfaces of the recesses RS are located at a level the same as or lower than a level of a bottom surface of the etch stop layer 143. A lateral surface of each of the etch stop layer 143, the second dielectric layer 144, and the polish stop layer 145 may be exposed at inner walls of the recesses RS.

A conductive layer 152 may be formed on the protection layer 140. The conductive layer 152 may fill the recesses RS while covering the protection layer 140. For example, a seed layer may be formed on the protection layer 140 to conformally cover a top surface of the protection layer 140 and inner sides of the recesses RS, and then the seed layer may be used as a seed to perform a plating process for forming the conductive layer 152. The conductive layer 152 may include a conductive material, such as copper (Cu).

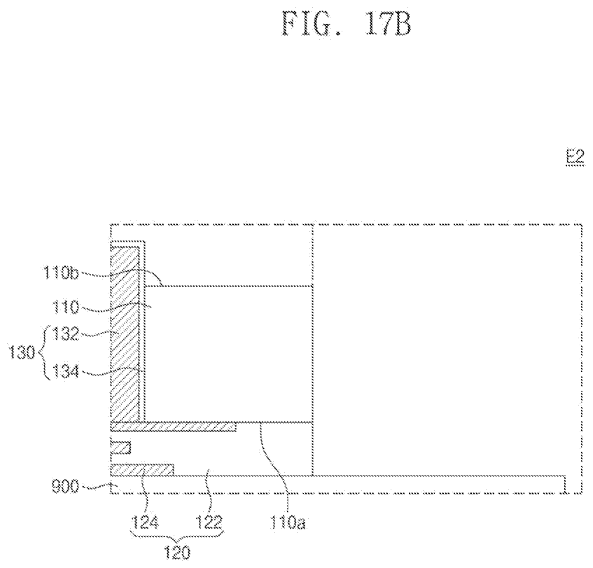

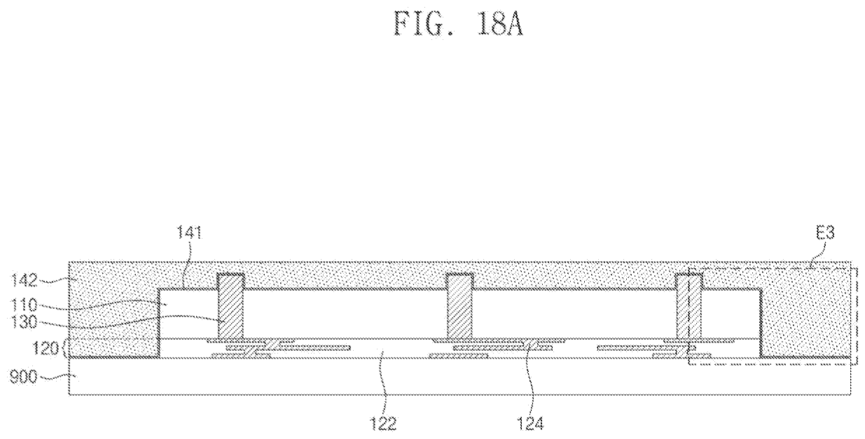

Referring to FIGS. 15A and 15B, a planarization process may be performed on the conductive layer 152. The planarization process may include a chemical mechanical polishing (CMP) process. The planarization process may be performed until the protection layer 140 and the polish stop layer 145 are exposed at top surfaces thereof. In the planarization process, the conductive layer 152 may be divided to form second chip pads 150. After the planarization process, the top surface of the protection layer 140 may be coplanar with the top surfaces of the second chip pads 150. The top surface of the protection layer 140 and the top surfaces of the second chip pads 150 may be substantially flat.

Afterwards, the carrier substrate 900 may be removed.

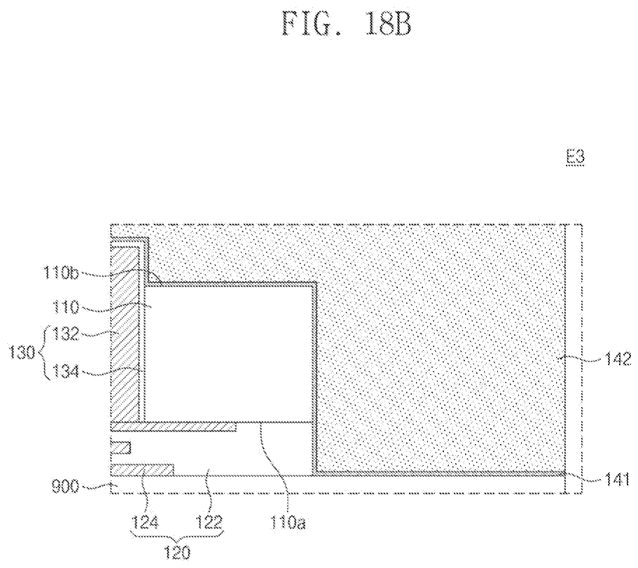

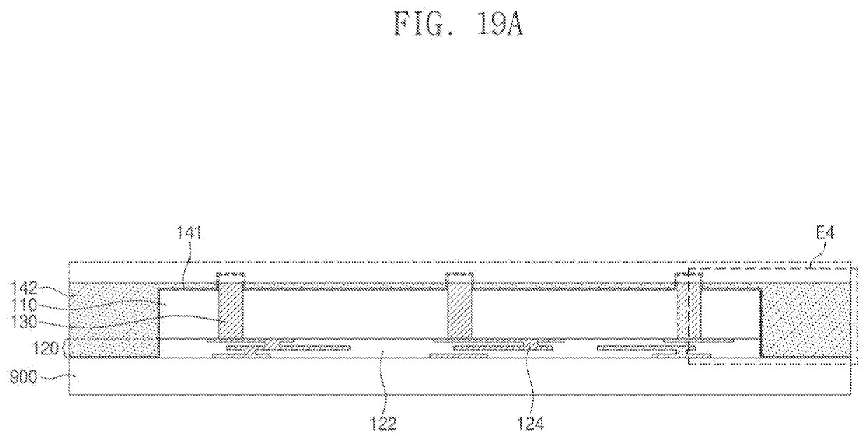

FIGS. 16A, 17A, 18A, 19A, 20A, 21A, 22A, and 23A illustrate cross-sectional views showing a method of fabricating a semiconductor package according to some embodiments of the present disclosure. FIGS. 16B, 17B, 18B, 19B, 20B, 21B, 22B, and 23B illustrate enlarged views showing sections E1, E2, E3, E4, E5, E6, E7, and E8 of FIGS. 16A, 17A, 18A, 19A, 20A, 21A, 22A, and 23A, respectively.

Referring to FIGS. 16A and 16B, as discussed with reference to FIGS. 9A and 9B, a carrier substrate 900 may be provided. According to some embodiments, a base chip may be provided to replace the carrier substrate 900. In this case, a circuit layer 120 and conductive posts 147 of a semiconductor chip that are discussed below may be coupled to chip pads of the base chip.

Integrated circuits may be formed on a semiconductor substrate to form a base layer 110, through vias 130 may be formed in the base layer 110, and a circuit layer 120 may be formed on a bottom surface 110a (e.g., active surface) of the base layer 110.

The base layer 110 may be provided on the carrier substrate 900. For example, the base layer 110 may be attached to the carrier substrate 900 to allow the circuit layer 120 to contact the carrier substrate 900. A width of the carrier substrate 900 may be greater than a width of the base layer 110. A portion of a top surface of the carrier substrate 900 may not be covered with the base layer 110.

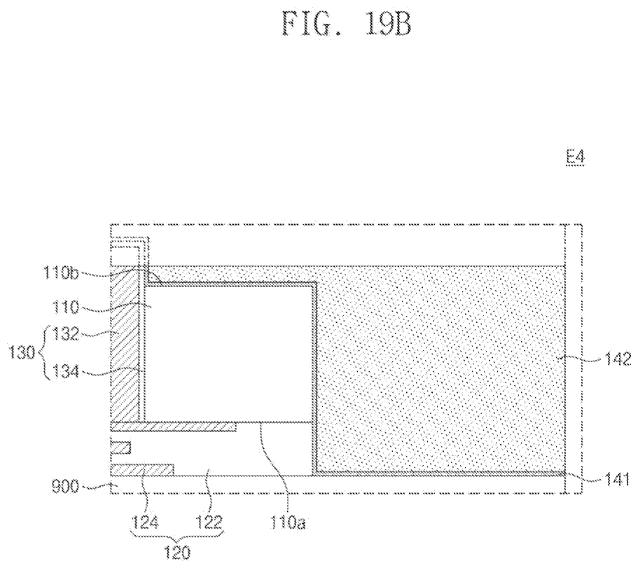

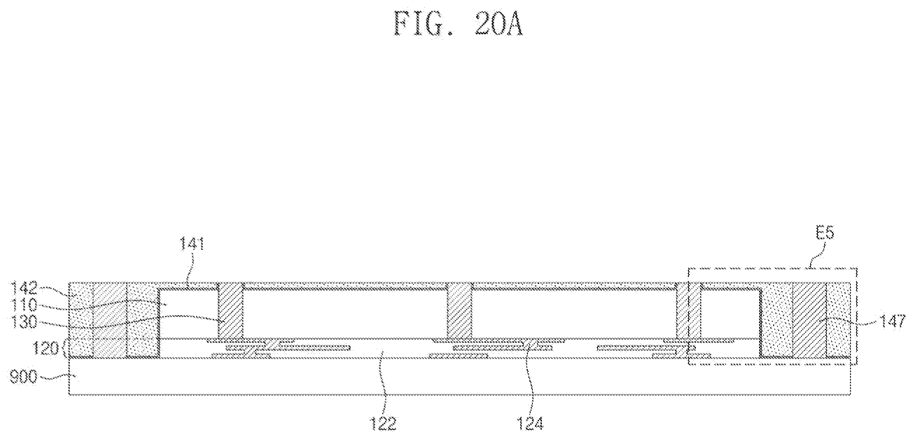

Referring to FIGS. 17A and 17B, a portion of the base layer 110 may be removed. For example, an upper portion of the base layer 110 may be etched. After the removal of the upper portion of the base layer 110, the through vias 130 may protrude from a top surface 110b of the base layer 110.

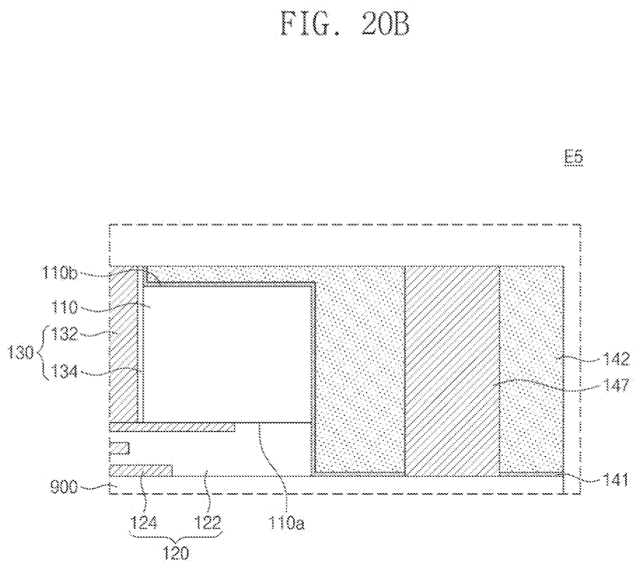

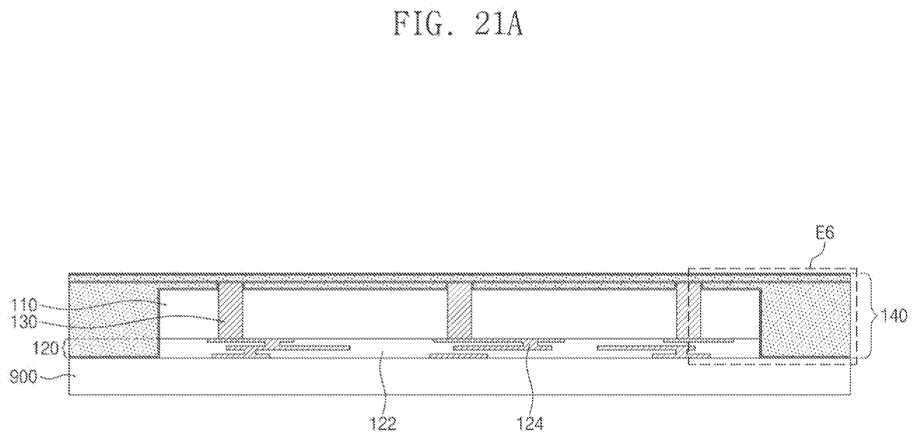

Referring to FIGS. 18A and 18B, a liner layer 141 may be formed on the carrier substrate 900. The liner layer 141 may be formed to conformally cover the base layer 110 and the through vias 130 that protrude from the top surface 110b of the base layer 110. The liner layer 141 may also be formed on one side of the base layer 110. For example, the liner layer 141 may cover a lateral surface of the base layer 110 and the top surface of the carrier substrate 900 on the one side of the base layer 110.

A first dielectric layer 142 may be formed on the carrier substrate 900. On the carrier substrate 900, the first dielectric layer 142 may surround and completely bury the base layer 110. Thus, the first dielectric layer 142 may completely cover the liner layer 141.

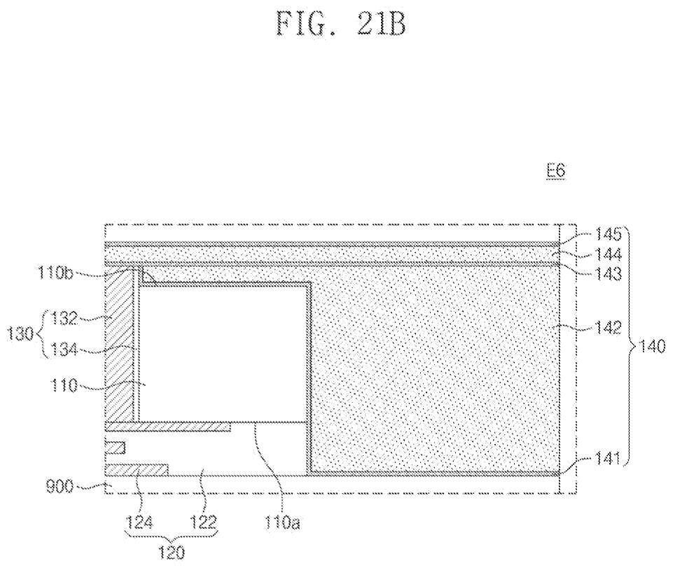

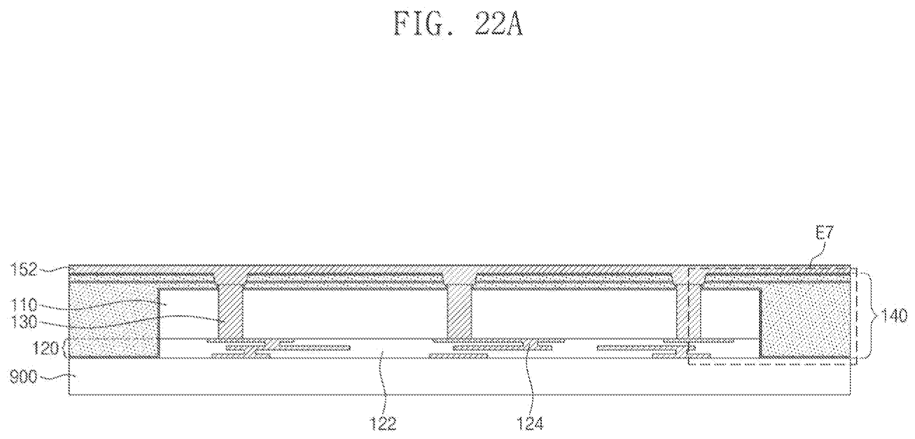

Referring to FIGS. 19A and 19B, a thinning process may be performed on the first dielectric layer 142. For example, a grinding process or a chemical mechanical polishing (CMP) process may be performed on a top surface of the first dielectric layer 142. The thinning process may be executed until the top surfaces of the through vias 130 are exposed. After the thinning process, the top surface of the conductive layer 132, a top end of the via barrier layer 134, a top end of the liner layer 141, and the top surface of the first dielectric layer 142 may be substantially flat and coplanar with each other.

FIGS. 18A, 18B, 19A, and 19B depict that a single-layered liner layer 141 is provided, but embodiments of the present disclosure are not limited thereto. According to some embodiments, before the formation of the first dielectric layer 142 that completely buries the through vias 130, a multiple layer may be formed to conformally cover the through vias 130 and the top surface 110b of the base layer 110. The multiple layer may include a liner layer, a dielectric layer, and a polish stop layer that are sequentially stacked. In this configuration, a thickness of the dielectric layer may be smaller than a protrusion distance of the through via 130. Afterwards, a thinning process may be performed on the multiple layer. The thinning process may be performed to surface of the polish stop layer on one side of the through vias 130, and the top surfaces the through vias 130 may be exposed. In the thinning process, the first dielectric layer 142 may be removed. A residual portion of the polish stop layer may be removed through a subsequent process. There may thus be formed the liner layer and the dielectric layer that surround the through vias 130. The liner layer that remains after the thinning process may serve as the liner layer 141 discussed with respect to FIGS. 18A, 18B, 19A, and 19B, and the dielectric layer that remains after the thinning process may serve as the first dielectric layer 142 discussed with respect to FIGS. 18A, 18B, 19A, and 19B. The following description will focus on the embodiment of FIGS. 18A, 18B. 19A, and 19B.

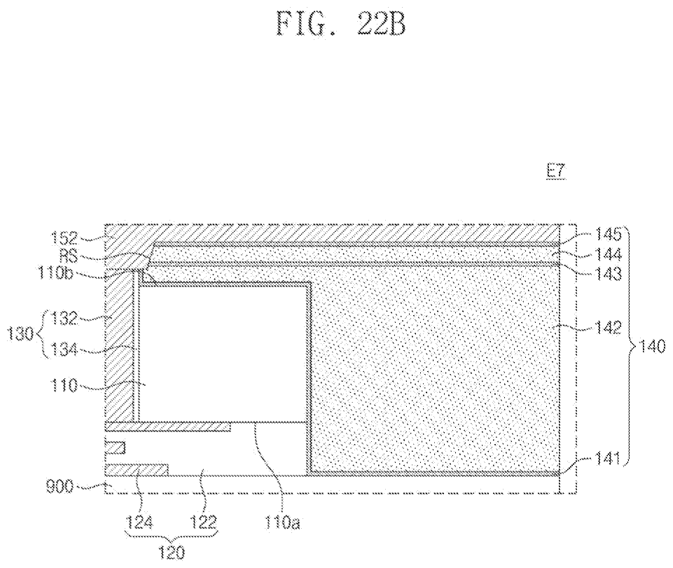

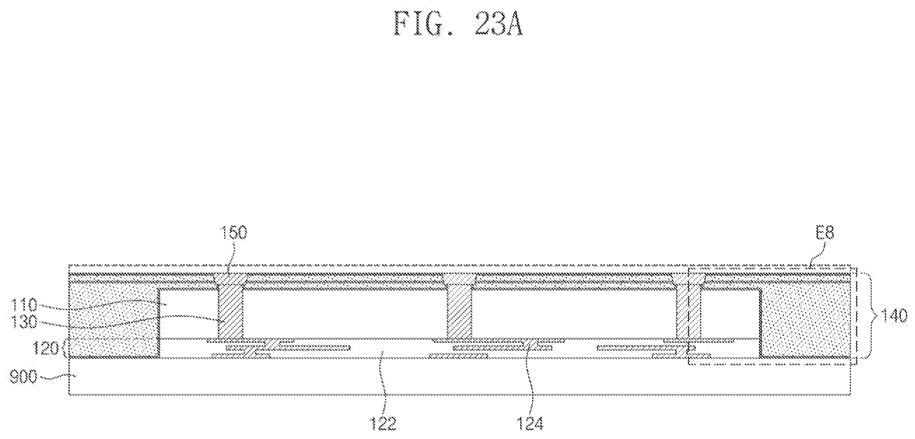

Referring to FIGS. 20A and 20B, conductive posts 147 may be formed on one side of the base layer 110. For example, on the one side of the base layer 110, through holes may be formed to vertically penetrate the first dielectric layer 142 and the liner layer 141 to expose the carrier substrate 900, and thereafter the through holes may be filled with a conductive material to form the conductive posts 147. The process for forming the conductive posts 147 may include an electroplating process. The conductive posts 147 may not be formed in some embodiments. The following description will be with reference to the embodiment of FIGS. 19A and 19B.

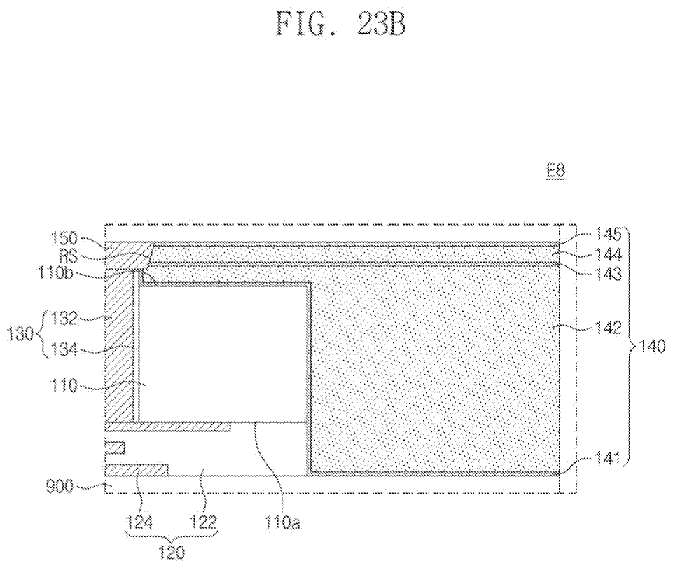

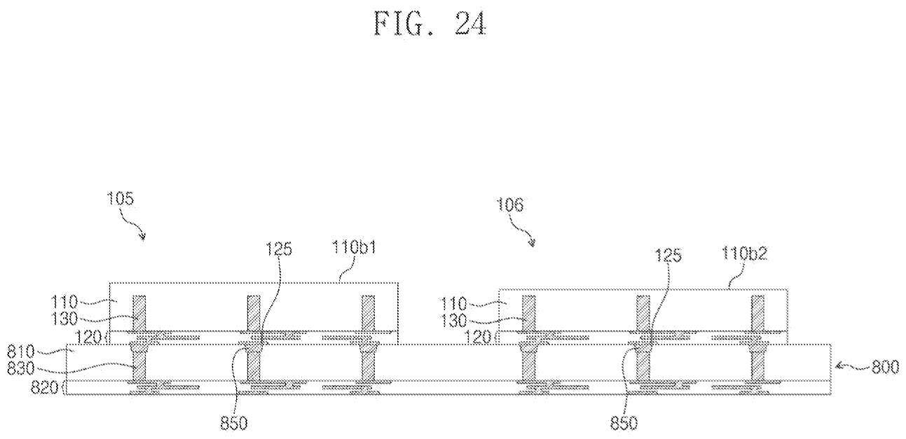

Referring to FIGS. 21A and 21B, an etch stop layer 143 may be formed on the carrier substrate 900 The etch stop layer 143 may conformally cover the top surface of the conductive layer 132, the top end of the via barrier layer 134, the top end of the liner layer 141, and the top surface of the first dielectric layer 142. The etch stop layer 143 may be shaped as a substantially flat planarized layer.

A second dielectric layer 144 may be formed on the etch stop layer 143. The etch stop layer 143 may separate the second dielectric layer 144 from the first dielectric layer 142. The second dielectric layer 144 may be shaped as a substantially flat planarized layer.

A polish stop layer 145 may be formed on the second dielectric layer 144. The polish stop layer 145 may be formed to cover the second dielectric layer 144. The polish stop layer 145 may be shaped as a substantially flat planarized layer.

According to some embodiments of the present disclosure, the protection layer 140 may be formed to surround the base layer 110 and the circuit layer 120. Therefore, irrespective of a size of the base layer 110 formed on a semiconductor substrate, a size of a semiconductor chip may be determined based on a size of the protection layer 140. It may be possible to form a semiconductor chip having various sizes, and to easily fabricate a semiconductor package in which different kinds of semiconductor chips are bonded to each other.

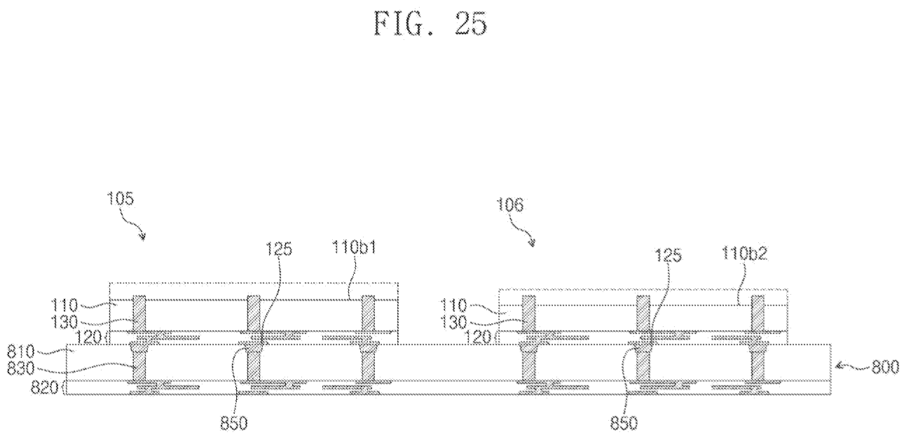

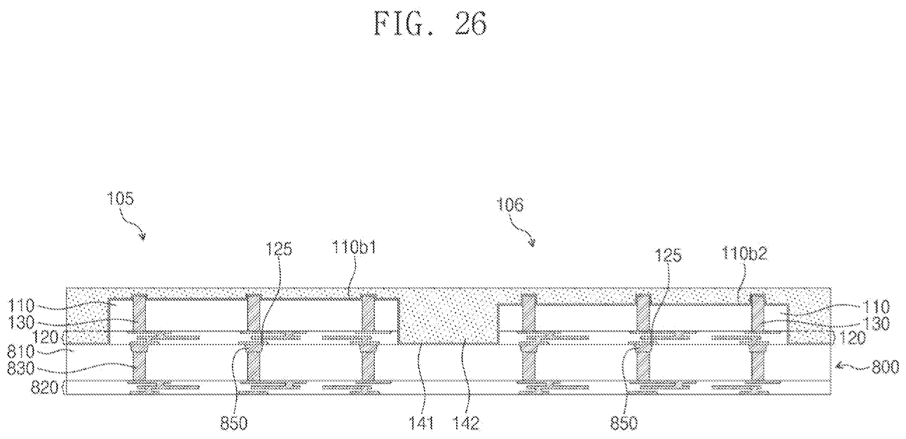

Referring to FIGS. 22A and 22B, a patterning process may be performed on the protection layer 140. In the patterning process, recesses RS may be formed on the protection layer 140 to expose the through vias 130. The patterning process may be performed until bottom surfaces of the recesses RS are located at a level the same as or lower than a level of a bottom surface of the etch stop layer 143.

A conductive layer 152 may be formed on the protection layer 140. The conductive layer 152 may fill the recesses RS while covering the protection layer 140.

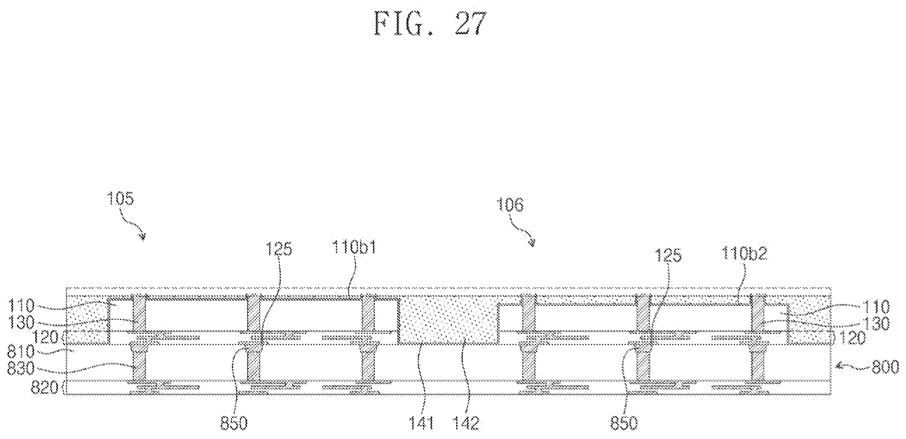

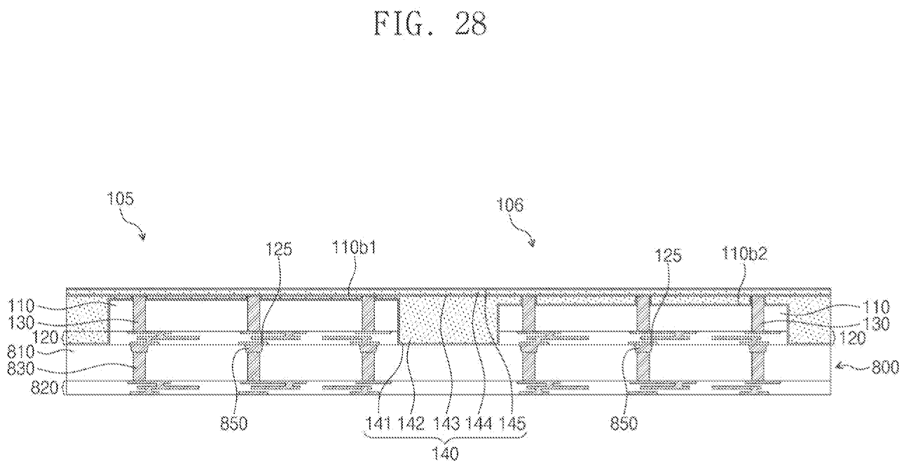

Referring to FIGS. 23A and 23B, a planarization process may be performed on the conductive layer 152. The planarization process may be performed until the protection layer 140 and the polish stop layer 145 are exposed at top surfaces thereof. In the planarization process, the conductive layer 152 may be divided to form second chip pads 150.

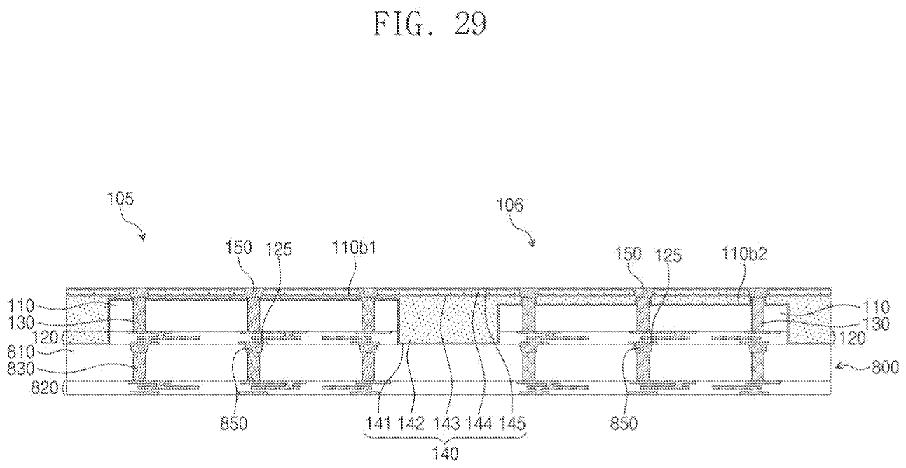

FIGS. 24 to 29 illustrate cross-sectional views showing a method of fabricating a semiconductor package according to some embodiments of the present disclosure.

Referring to FIG. 24, a base substrate 800 may be formed. For example, a typical process may be performed to form semiconductor devices, such as transistors, on a front surface of a base semiconductor substrate 810. A base circuit layer 820 may be formed by forming a dielectric pattern and a wiring pattern on the front surface of the base semiconductor substrate 810. Base vias 830 may be performed to vertically penetrate from the front surface into the base semiconductor substrate 810. Mount pads 850 may be formed on a rear surface of the base substrate 800.

A fifth semiconductor chip 105 and a sixth semiconductor chip 106 may be bonded to or mounted on the base substrate 800. Each of the fifth semiconductor chip 105 and the sixth semiconductor chip 106 may be substantially the same as one of the semiconductor chips discussed with reference to FIGS. 1 and 2A to 2E. The fifth semiconductor chip 105 and the sixth semiconductor chip 106 may have thicknesses that are different from each other in accordance with process variation of fabrication process for the fifth semiconductor chip 105 and the sixth semiconductor chip 106. The through vias 130 of the fifth semiconductor chip 105 and the sixth semiconductor chip 106 may be located at the same level as the base substrate 800, and the base layers 110 of the fifth semiconductor chip 105 and the sixth semiconductor chip 106 may have their top surfaces (or rear surfaces) 110b1 and 110b2 located at different levels from the base substrate 800. For example, the fifth semiconductor chip 105 and the sixth semiconductor chip 106 may be formed from a single wafer. In this case, in a thinning process performed on the top surfaces 110b1 and 110b2 of the fifth semiconductor chip 105 and the sixth semiconductor chip 106, the degree of polishing of the wafer may be changed depending on positions of the fifth semiconductor chip 105 and the sixth semiconductor chip 106. FIG. 24 illustrates an example where the top surface 110b1 of the base layer 110 included in the fifth semiconductor chip 105 is located at a higher level than a level of the top surface 110b2 of the base layer 110 included in the sixth semiconductor chip 106.

Referring to FIG. 25, a removal action may be performed on an upper portion of the base layer 110 of each of the fifth semiconductor chip 105 and the sixth semiconductor chip 106. After the removal of the upper portion of the base layer 110, the through vias 130 may protrude from a top surface of the base layer 110. In the process for removing the upper portion of the base layer 110, a polish or etch depth of the base layer 110 included in the fifth semiconductor chip 105 may be substantially the same as a polish or etch depth of the base layer 110 included in the sixth semiconductor chip 106. Therefore, the top surfaces 110b1 and 110b2 of the base layers 110 included in the fifth semiconductor chip 105 and the sixth semiconductor chip 106 may be located at different levels from the base substrate 800. In addition, a protrusion distance of the through vias 130 that protrude from the base layer 110 of the fifth semiconductor chip 105 may be smaller than a protrusion distance of the through vias 130 that protrude from the base layer 110 of the sixth semiconductor chip 106.

Referring to FIG. 26, a liner layer 141 may be formed on the base substrate 800. The liner layer 141 may be formed to conformally cover the fifth semiconductor chip 105 and the sixth semiconductor chip 106 and a top surface of the base substrate 800. On the base layers 110 of the fifth semiconductor chip 105 and the sixth semiconductor chip 106, the liner layer 141 may conformally cover the through vias 130 and the top surfaces 110b1 and 110b2 of the base layers 110.

A first dielectric layer 142 may be formed on the base substrate 800. On the base substrate 800, the first dielectric layer 142 may completely bury the fifth semiconductor chip 105 and the sixth semiconductor chip 106. For example, the first dielectric layer 142 may completely cover the liner layer 141.

Referring to FIG. 27, a thinning process may be performed on the first dielectric layer 142. For example, a grinding process or a chemical mechanical polishing (CMP) process may be performed on a top surface of the first dielectric layer 142. The thinning process may continue until the through vias 130 of the fifth semiconductor chip 105 and the sixth semiconductor chip 106 are exposed at top surfaces thereof. The first dielectric layer 142 and the through vias 130 may have their top surfaces that are substantially flat and coplanar with each other. As the fifth semiconductor chip 105 and the sixth semiconductor chip 106 have different thicknesses from each other, after the thinning process, a thickness of the first dielectric layer 142 on the base layer 110 of the fifth semiconductor chip 105 may be smaller than a thickness of the first dielectric layer 142 on the base layer 110 of the sixth semiconductor chip 106.

Referring to FIG. 28, an etch stop layer 143, a second dielectric layer 144, and a polish stop layer 145 may be sequentially formed on the base substrate 800. The etch stop layer 143, the second dielectric layer 144, and the polish stop layer 145 may each be shaped as a substantially flat planarized layer.

Referring to FIG. 29, the protection layer 140 may undergo a patterning process to form recesses that expose the through vias 130. A conductive layer may be formed to cover the protection layer 140 and to fill the recesses. A planarization process may be performed on the conductive layer 152 such that the conductive layer may be divided to form second chip pads 150.

According to some embodiments of the present disclosure, in a process for exposing the through vias 130, the through vias 130 and the first dielectric layer 142 may be simultaneously etched and may have their top surfaces coplanar with each other. Therefore, the etch stop layer 143 may be located at the same level on the fifth semiconductor chip 105 and the sixth semiconductor chip 106 having different heights, and the recesses may have the same depth at the same level, wherein the recesses are formed by an etching process in which the etch stop layer 143 is used as am etch stopper. For example, even when using the base layers 110 whose thicknesses are different from each other, the protection layers 140 of the fifth semiconductor chip 105 and the sixth semiconductor chip 106 fabricated by the process mentioned above may have their top surfaces located at the same level. Accordingly, in fabrication process, it may be possible to achieve a uniform process variation in thickness of semiconductor chips and also in size and shape of a semiconductor package.

Afterwards, other semiconductor chips may be bonded onto the fifth semiconductor chip 105 and the sixth semiconductor chip 106, and a molding layer may be formed on the base substrate 800 to cover the fifth semiconductor chip 105 and the sixth semiconductor chip 106.

In a semiconductor package according to some embodiments of the present disclosure, an etch stop layer interposed between dielectric layers of a protection layer may completely cover a top surface of a lower dielectric layer and a bottom surface of an upper dielectric layer, and may be shaped as a planarized layer. A polish stop layer and the lower dielectric layer formed on the etch stop layer may also be shaped as a planarized layer or may have a plate shape, and a top surface of the protection layer and a top surface of a chip pad may be substantially flat and coplanar with each other. Therefore, in a direct bonding process where semiconductor chips are in direct contact with each other, another semiconductor chip may be easily bonded onto a top surface of a semiconductor chip.

In a semiconductor package, no gap may be present between the semiconductor chips or between the dielectric pattern and the protection layer. Therefore, good contact may be provided between the dielectric pattern and the protection layer or between the semiconductor chips, and the semiconductor package may improve in structural stability. In addition, an interval may be absent between chip pads of the semiconductor chips. Accordingly, it may be possible to provide a semiconductor package which has good bonding between the chip pads and a good electrical connection between the semiconductor chips.

In a semiconductor package, the protection layer extending onto a lateral surface of a base layer may be used to adjust a width of the semiconductor chip. Thus, the semiconductor chip may be easily bonded to another semiconductor chip or an electronic element whose size is different from that of the semiconductor chip.

1. A semiconductor package, comprising:
a first structure; and
a second structure,
wherein the first structure comprises: a first semiconductor substrate that has an active surface on which a first semiconductor device is configured to be provided, and an inactive surface opposite to the active surface;
a first through via that vertically penetrates the first semiconductor substrate and protrudes from the inactive surface of the first semiconductor substrate;
a first protection layer that covers the inactive surface of the first semiconductor substrate and buries the first through via; and
a first pad that penetrates at least a portion of the first protection layer and is coupled to the first through via,
wherein the first protection layer comprises:
a first dielectric layer that is on the inactive surface of the first semiconductor substrate;
a second dielectric layer on the first dielectric layer; and
an etch stop layer between the first dielectric layer and the second dielectric layer and in contact with a lateral surface of the first pad,
wherein the second structure comprises a second pad,
wherein the first structure and the second structure are bonded to each other, and
wherein the first pad and the second pad are in contact with each other.

2. The semiconductor package of claim 1, wherein the etch stop layer separates the first dielectric layer from the second dielectric layer.

3. The semiconductor package of claim 1, wherein a distance from the etch stop layer to the first semiconductor substrate is greater than a distance from a bottom surface of the first pad to the first semiconductor substrate.

4. The semiconductor package of claim 1, wherein the first through via vertically penetrates at least a portion of the first dielectric layer, and
wherein the first pad vertically penetrates the second dielectric layer and the etch stop layer.

5. The semiconductor package of claim 1, wherein a distance between a contact interface, between the first through via and the first pad, and the first semiconductor substrate is smaller than a distance between a top surface of the first dielectric layer and the first semiconductor substrate.

6. The semiconductor package of claim 1, wherein the first through via comprises:
a conductive layer that has a pillar shape; and
a via barrier layer that surrounds a circumferential surface of the conductive layer, and
wherein the first pad is in contact with a top surface of the conductive layer and a top surface of the via barrier layer.

7. The semiconductor package of claim 1, wherein the first protection layer further comprises a liner layer that covers a bottom surface of the first dielectric layer that faces towards the first semiconductor substrate,
wherein the liner layer extends from between the first semiconductor substrate and the first dielectric layer to between a lateral surface of the through via and the first dielectric layer.

8. The semiconductor package of claim 7, wherein an end of the liner layer extends along the lateral surface of the through via and contacts a bottom surface of the first pad.

9. The semiconductor package of claim 1, wherein the first protection layer further comprises a polish stop layer that covers a top surface of the second dielectric layer that faces away from the first semiconductor substrate,
wherein a top surface of the polish stop layer is coplanar with a top surface of the first pad.

10. The semiconductor package of claim 1, wherein a top surface of the first pad and a top surface of the first protection layer are flat.

11. The semiconductor package of claim 1, wherein the first dielectric layer and the second dielectric layer comprise silicon oxide (SiO), and
wherein the etch stop layer comprises silicon nitride (SiN).

12.-13. (canceled)

14. A semiconductor package, comprising:
a substrate;
semiconductor chips on the substrate; and
a molding layer on the substrate, the molding layer surrounding the semiconductor chips,
wherein each of the semiconductor chips comprises:
a semiconductor substrate;
first pads on an active surface of the semiconductor substrate;
a dielectric pattern that surrounds the first pads and exposes one surface of the first pads;
second pads on an inactive surface of the semiconductor substrate;
a protection layer that surrounds the second pads and exposes one surface of the second pads; and
through vias that vertically penetrate the semiconductor substrate and are connected to the second pads,
wherein the protection layer comprises a first dielectric layer, an etch stop layer, and a second dielectric layer that are sequentially stacked, the first dielectric layer and the second dielectric layer being spaced apart from each other across the etch stop layer,
wherein a distance from the etch stop layer to the semiconductor substrate is greater than a distance from bottom surfaces of the second pads to the semiconductor substrate, and
wherein one of the semiconductor chips is directly bonded to another one of the semiconductor chips, and the first pads of the one of the semiconductor chips are in contact with the second pads of the other one of the semiconductor chips.

15. The semiconductor package of claim 14, wherein the etch stop layer is in contact with lateral surfaces of the second pads.

16. The semiconductor package of claim 14, wherein the through vias vertically penetrate at least a portion of the first dielectric layer,
wherein the second pads vertically penetrate the second dielectric layer and the etch stop layer, and
wherein a distance between a contact interface, between one of the through vias and one of the second pads, and the semiconductor substrate is smaller than a distance between a top surface of the first dielectric layer and the semiconductor substrate.

17. The semiconductor package of claim 14, wherein each of the through vias comprises:
a conductive layer that has a pillar shape; and
a via barrier layer that surrounds a circumferential surface of the conductive layer,
wherein one of the second pads is in contact with a top surface of the conductive layer and a top surfaces of the via barrier layer.

18. The semiconductor package of claim 14, wherein the protection layer further comprises a liner layer that covers a bottom surface of the first dielectric layer that faces towards the semiconductor substrate,
wherein the liner layer extends from between the semiconductor substrate and the first dielectric layer to between a lateral surface of one of the through vias and the first dielectric layer.

19. The semiconductor package of claim 18, wherein an end of the liner layer extends along the lateral surface of one of the through vias and contacts a bottom surface of one of the second pads.

20. The semiconductor package of claim 14, wherein the protection layer further comprises a polish stop layer that covers a top surface of the second dielectric layer that faces away from the semiconductor substrate,
wherein a top surface of the polish stop layer is coplanar with top surfaces of the second pads.

21. The semiconductor package of claim 14, wherein top surfaces of the second pads and a top surface of the protection layer are flat.

22.-23. (canceled)

24. A semiconductor package, comprising:
a substrate;
semiconductor chips stacked on the substrate; and
a molding layer on the substrate, the molding layer surrounding the semiconductor chips,
wherein each of the semiconductor chips comprises:
a semiconductor substrate;
first pads on an active surface of the semiconductor substrate;
a dielectric pattern that surrounds the first pads and exposes one surface of the first pads;
a protection layer that is on an inactive surface of the semiconductor substrate and comprises a first dielectric layer, an etch stop layer, a second dielectric layer, and a polish stop layer that are sequentially stacked;
second pads that are in the protection layer and have one surface exposed by the protection layer; and
through vias that vertically penetrate the semiconductor substrate and are connected to the second pads,
wherein the etch stop layer is in contact with the second pads, and
wherein one of the semiconductor chips is directly bonded to another one of the semiconductor chips, and the first pads of the one of the semiconductor chips are in contact with the second pads of the other one of the semiconductor chips.

25.-40. (canceled)
